(19) United States
(12) Patent Application Publication
(10) Pub. No.: US 2012/0061816 A1
(43) Pub. Date: Mar. 15, 2012

(54) SEMICONDUCTOR PACKAGE AND METHOD OF FABRICATING THE SAME

(75) Inventors: Sang-Sub SONG, Suwon-si (KR); Sang-Ho An, Suwon-si (KR); Joon-Young Oh, Seongnam-si (KR); Dong-Ok Kwak, Suwon-si (KR); Joon-Ki Park, Suwon-si (KR)

(73) Assignee: Samsung Electronics Co., Ltd., Suwon-si (JP)

(21) Appl. No.: 13/227,940

(22) Filed: Sep. 8, 2011

(30) Foreign Application Priority Data
Sep. 10, 2010 (KR) 10-2010-0089104

(51) Int. Cl. H01L 23/50; H01L 23/52

(52) U.S. Cl. 257/696; 257/784; 257/E23.079; 257/E23.141

(57) ABSTRACT

Provided are a semiconductor package and method of fabricating the same. The package includes an interconnection substrate, a semiconductor chip mounted on the interconnection substrate, a lateral wire bonded on the interconnection substrate and configured to enclose a side surface of the semiconductor chip, and a metal layer disposed on the semiconductor chip and electrically connected to the lateral wire.

### CROSS-REFERENCE TO RELATED APPLICATIONS

This application claims the benefit of priority under 35 U.S.C. §119 to Korean Patent Application No. 10-2010-0089104 filed on Sep. 10, 2010, the disclosure of which is hereby incorporated by reference in its entirety.

### BACKGROUND OF THE INVENTION

1. Field of the Invention

The present general inventive concept generally relates to a semiconductor package and a method of fabricating the same.

2. Description of the Related Art

In recent years, portable electronic apparatuses, such as portable phones, personal digital assistants (PDAs), and smart phones, have provided various functions. Thus, various semiconductor packages may be used for the portable electronic apparatuses. However, an increase in the clock frequency of processors or memories of portable electronic apparatuses can cause a problem of electromagnetic interference (EMI). Thus, there is a need to provide electromagnetic shielding for semiconductor packages.

### SUMMARY OF THE INVENTION

Embodiments of the inventive concept provide a semiconductor package that provides electromagnetic shielding and a method of fabricating the same.

Other embodiments of the inventive concept provide a semiconductor module including a semiconductor package and an electronic system including a semiconductor package.

The technical objectives of the inventive disclosure are not limited to the above disclosure; other objectives may become apparent to those of ordinary skill in the art based on the following descriptions. Additional aspects and advantages of the present general inventive concept will be set forth in part in the description which follows and, in part, will be obvious from the description, or may be learned by practice of the general inventive concept.

The foregoing and/or other features and utilities of the present general inventive concept may be realized by a semiconductor package including an interconnection substrate, a semiconductor chip mounted on the interconnection substrate, a lateral wire bonded to the interconnection substrate and configured to enclose a side surface of the semiconductor chip, and a metal layer disposed on the semiconductor chip and electrically connected to the lateral wire.

The lateral wire may have a loop with a predetermined height and be is formed along an outer region of the interconnection substrate.

The lateral wire may be arranged in a plurality of columns.

Two adjacent columns of the lateral wire may be bonded to cross each other.

The semiconductor package may further include a molding member disposed between a side surface of the semiconductor chip and the lateral wire and between a top surface of the semiconductor chip and the metal layer.

The foregoing and/or other features and utilities of the present general inventive concept may be also realized by a semiconductor package including an interconnection substrate, a semiconductor chip mounted on a central region of the interconnection substrate, a plurality of ground pads formed on an outer region of the interconnection substrate, a molding member configured to cover the semiconductor chip, a metal layer formed on the molding member, and a plurality of lateral wires configured to electrically connect at least one of the plurality of ground pads and the metal layer, and to enclose a side surface of the semiconductor chip. A peak of at least one of the plurality of lateral wires is exposed in a top surface of the molding member.

The plurality of lateral wires may electrically connect the plurality of ground pads to each other.

A distance between two adjacent lateral wires of the plurality of lateral wires may become different from the interconnection substrate to the metal layer.

Two adjacent lateral wires of the plurality of lateral wires may be bent toward each other.

Two adjacent lateral wires may be bent away from each other.

The plurality of ground pads may be formed in a plurality of columns along the outer region of the interconnection substrate.

The plurality of lateral wires may electrically connect ground pads in one column of the plurality of ground pads to each other.

Two adjacent ground pads out of the plurality of ground pads may be directly connected to one another by a corresponding one of the plurality of lateral wires.

The molding member may include at least one groove by which the at least one peak of the plurality of lateral wires is exposed.

At least one of the plurality of lateral wires may connect between the plurality of ground pads and the metal layer by the shortest route.

The molding member may cover side surfaces of the plurality of lateral wires.

The foregoing and/or other features and utilities of the present general inventive concept may be also realized by a semiconductor package including an interconnection substrate including a first region and a second region disposed outside the first region, at least one semiconductor chip mounted on the first region of the interconnection substrate, a plurality of ground pads formed on the second region of the interconnection substrate along the outline of the interconnection substrate, a molding member configured to cover top and side surfaces of the at least one semiconductor chip, a plurality of lateral wires electrically connected to the plurality of ground pads, the plurality of lateral wires having at least one peak exposed in a top surface of the molding member, and a metal layer formed on the molding member and electrically connected to the at least one peak of the plurality of lateral wires. Herein, the plurality of lateral wires enclose the side surfaces of the at least one semiconductor chip.

A region of the molding member corresponding to the second region of the interconnection substrate may have a lower height than a region of the molding member corresponding to the first region of the interconnection substrate.

Two adjacent lateral wires out of the plurality of lateral wires may have an arch shape.

The semiconductor package may further include at least one signal pad formed on the interconnection substrate and at least one signal wire configured to electrically connect between the at least one signal pad and the at least one semiconductor chip. The at least one signal pad may be disposed between the at least one semiconductor chip and the plurality of ground pads, and the at least one signal wire may be formed of the same material as the plurality of lateral wires.

A semiconductor package including an interconnection substrate, a semiconductor chip mounted on a central region of the interconnection substrate, a plurality of lateral wires, each of the plurality of lateral wires having at least a first end bonded to an outer region of the interconnection substrate, a molding member disposed on the interconnection substrate to cover the semiconductor chip and at least part of the plurality of lateral wires, and a metal layer disposed on the molding member above the semiconductor chip and electrically connected to a second end of at least one of the plurality of lateral wires.

At least one of the plurality of lateral wires may have an arch shape.

The molding member corresponding to the outer region may be lower than the molding member corresponding to the central region.

The plurality of lateral wires surround lateral sides of the semiconductor chip.

The molding member may include grooves such that the plurality of lateral wires disposed in the area of the groove contact the metal layer and the plurality of lateral wires not disposed in the area of the groove do not contact the metal layer.

### BRIEF DESCRIPTION OF THE DRAWINGS

The foregoing and other features and advantages of the inventive concepts will be apparent from the more particular description of embodiments of the general inventive concepts, as illustrated in the accompanying drawings in which like reference characters refer to the same parts throughout the different views. The drawings are not necessarily to scale, emphasis instead being placed upon illustrating the principles of the inventive concepts. In the drawings:

FIG. 1 is a plan view of a semiconductor package according to a first embodiment of the general inventive concept;

FIG. 2A is a longitudinal sectional view taken along line I-I′ of FIG. 1;

FIG. 2B is a longitudinal sectional view taken along line II-II′ of FIG. 1;

FIG. 3A is a partial plan view of a semiconductor package according to a second embodiment of the general inventive concept;

FIG. 3B is a longitudinal sectional view taken along line III-III′ of FIG. 3A;

FIG. 4A is a partial plan view of a semiconductor package according to a third embodiment of the general inventive concept;

FIG. 4B is a longitudinal sectional view taken along line IV-IV′ of FIG. 4A;

FIG. 5A is a partial plan view of a semiconductor package according to a fourth embodiment of the general inventive concept;

FIG. 5B is a longitudinal sectional view taken along line V-V′ of FIG. 5A;

FIG. 6A is a partial plan view of a semiconductor package according to a fifth embodiment of the general inventive concept;

FIG. 6B is a longitudinal sectional view taken along line VI-VI′ of FIG. 6A;

FIG. 7A is a partial plan view of a semiconductor package according to a sixth embodiment of the general inventive concept;

FIG. 7B is a longitudinal sectional view taken along line VII-VII′ of FIG. 7A;

FIG. 8A is a partial plan view of a semiconductor package according to a seventh embodiment of the general inventive concept;

FIG. 8B is a longitudinal sectional view taken along line VIII-VIII′ of FIG. 8A;

FIG. 9A is a partial plan view of a semiconductor package according to eighth and ninth embodiments of the general inventive concept;

FIG. 9B is a longitudinal sectional view taken along line IX-IX′ of FIG. 9A, which illustrates the semiconductor package according to the eighth embodiment of the general inventive concept;

FIG. 9C is a longitudinal sectional view taken along line IX-IX′ of FIG. 9A, which illustrates the semiconductor package according to the ninth embodiment of the general inventive concept;

FIG. 10 is a partial plan view of a semiconductor package according to a tenth embodiment of the general inventive concept;

FIG. 11A is a longitudinal sectional view taken along line X-X′ of FIG. 10;

FIG. 11B is a longitudinal sectional view taken along line XI-XI′ of FIG. 10;

FIG. 12A is a partial plan view of a semiconductor package according to an eleventh embodiment of the general inventive concept;

FIG. 12B is a longitudinal sectional view taken along line XII-XII′ of FIG. 12A;

FIGS. 13A through 13C are longitudinal sectional views of semiconductor packages according to twelfth through fourteenth embodiments of the general inventive concept;

FIG. 14A is a partial plan view of a semiconductor package according to a fifteenth embodiment of the general inventive concept;

FIG. 14B is a longitudinal sectional view taken along line XIII-XIII′ of FIG. 14A;

FIG. 15 is a longitudinal sectional view of a semiconductor package according to a sixteenth embodiment of the general inventive concept;

FIG. 16 is a longitudinal sectional view of a semiconductor package according to a seventeenth embodiment of the general inventive concept;

FIGS. 17A through 17G are partial plan views of semiconductor packages according to eighteenth through twenty-fourth embodiments of the general inventive concept;

FIGS. 18A, 19A, 20A, 21A, 22A, and 23A are longitudinal sectional views taken along line I-I′ of FIG. 1, which illustrate a first method of fabricating a semiconductor package according to embodiments of the general inventive concept;

FIGS. 18B, 19B, 20B, 21B, 22B, and 23B are longitudinal sectional views taken along line II-II′ of FIG. 1, which illustrate the first method of fabricating the semiconductor package according to the embodiments of the general inventive concept;

FIGS. 24A, 25A, and 26A are longitudinal sectional views taken along line X-X′ of FIG. 10, which illustrate a second method of fabricating a semiconductor package according to embodiments of the general inventive concept;

FIGS. 24B, 25B, and 26B are longitudinal sectional views taken along line XI-XI′ of FIG. 10, which illustrate the second method of fabricating the semiconductor package according to the embodiments of the general inventive concept;

FIG. 27 is a construction diagram of a semiconductor module using a semiconductor package according to embodiments of the general inventive concept; and

FIG. 28 is a construction diagram of an electronic system including a semiconductor package according to embodiments of the general inventive concept.

### DETAILED DESCRIPTION OF THE PREFERRED EMBODIMENTS

Reference will now be made in detail to embodiments of the present general inventive concept, examples of which are illustrated in the accompanying drawings, wherein like reference numerals refer to the like elements throughout. The embodiments are described below in order to explain the present general inventive concept while referring to the figures. The general inventive concept may, however, be embodied in different forms and should not be construed as limited to the embodiments set forth herein. Rather, these embodiments are provided so that this disclosure is thorough and complete and fully conveys the general inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

The terminology used herein is for the purpose of describing particular embodiments only and is not intended to be limiting of the general inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this general inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

### Embodiment 1

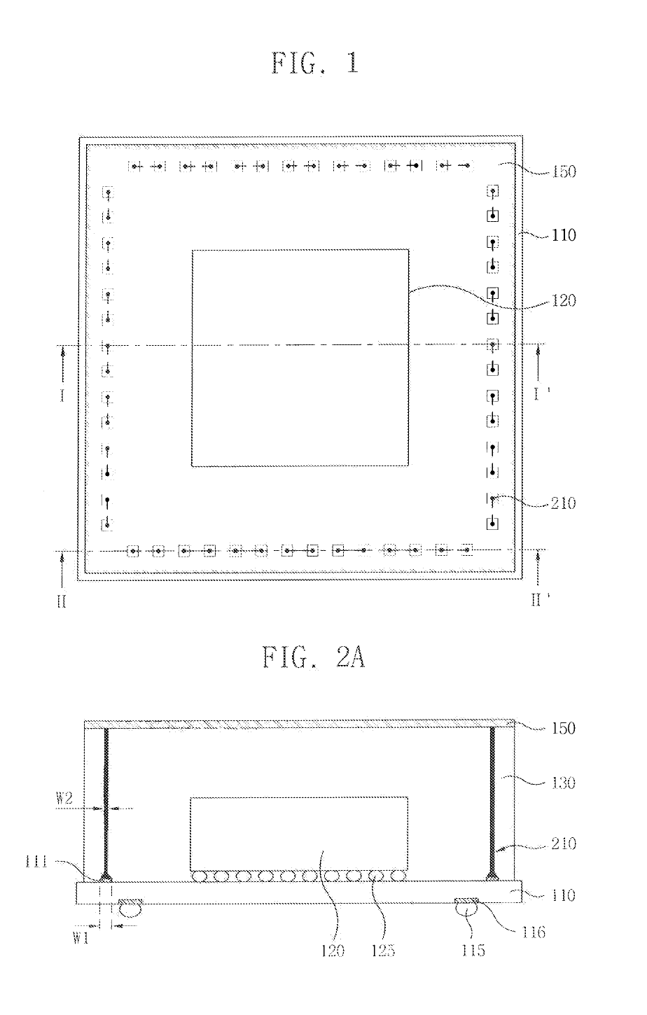

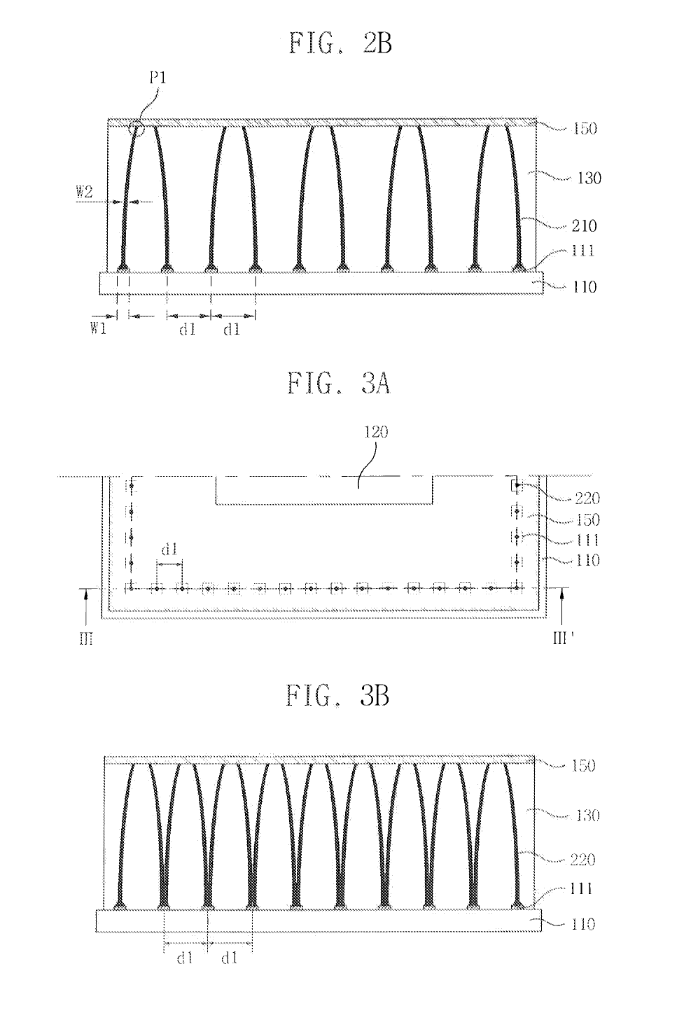

FIG. 1 is a plan view of a semiconductor package according to a first embodiment of the general inventive concept. FIG. 2A is a longitudinal sectional view taken along line I-I′ of FIG. 1, and FIG. 2B is a longitudinal sectional view taken along line II-II′ of FIG. 1.

Referring to FIGS. 1, 2A, and 2B, the semiconductor package according to the first embodiment may include an interconnection substrate 110, a semiconductor chip 120 mounted on a central region of the interconnection substrate 110, a plurality of ground pads 111 formed on an outer region of the interconnection substrate 110, a molding member 130 configured to cover the semiconductor chip 120, a metal layer 150 formed on the molding member 130, and a plurality of first lateral wires 210 configured to electrically connect the plurality of ground pads 111 and the metal layer 150, and to enclose a side surface of the semiconductor chip 120.

The interconnection substrate 110 may be a printed circuit board (PCB), a lead frame (LF), a tape interconnection, a ceramic substrate, or a silicon substrate. Here, the PCB may be any one of a rigid PCB, a flexible PCB, and a rigid-flexible PCB.

The interconnection substrate 110 may include a plurality of conductive lands 116 formed on a bottom surface thereof and a plurality of conductive bumps 115 bonded to the plurality of conductive lands 116, respectively. The plurality of conductive lands 116 and the plurality of conductive bumps 115 may include at least one selected from the group including gold (Au), silver (Ag), copper (Cu), nickel (Ni), aluminum (Al), tin (Sn), lead (Pb), platinum (Pt), bismuth (Bi), indium (In), and an alloy thereof.

The plurality of conductive bumps 115 may electrically connect the semiconductor package according to the first embodiment with a module board (not shown) or a main circuit board (not shown).

The plurality of ground pads 111 may have ground characteristics. To this end, the plurality of ground pads 111 may be electrically connected to at least one of the plurality of conductive bumps 115.

The plurality of first lateral wires 210 may be bonded to the plurality of ground pads 111. To this end, the plurality of ground pads 111 may have a first diameter W1. The first diameter W1 may be greater than a second diameter W2 of the plurality of first lateral wires 210. The first diameter W1 may be twice to three times the second diameter W2.

Two adjacent ones of the plurality of ground pads 111 may be spaced a first distance d1 apart from each other. The first distance d1 may be such a distance as to shield electromagnetic waves caused by the semiconductor chip 120. Specifically, the first distance d1 may be inversely proportional to a clock frequency of the semiconductor chip 120. For example, the first distance d1 may be equal to or less than 1/10 the wavelength λ of a clock frequency of the semiconductor chip 120. The distance d1 may range from 50 to 100 μm.

The plurality of ground pads 111 may be formed of a conductive material. For example, the plurality of ground pads 111 may include at least one selected from the group including Au, Ag, Cu, Ni, Al, Sn, Pb, Pt, Bi, In, and an alloy thereof.

The plurality of ground pads 111 may be formed on some of four side surfaces of the interconnection substrate 110. Thus, the plurality of first lateral wires 210 electrically connected to the plurality of ground pads 111 may enclose some of the side surface of the semiconductor chip 210.

The semiconductor chip 120 may include any one selected from the group including a dynamic random access memory (DRAM) chip, a static RAM (SRAM) chip, a flash memory chip, a phase-charge memory chip, a magnetic RAM (MRAM) chip, a resistive memory chip, and a logic chip. The semiconductor chip 120 may be a semiconductor circuit including a transistor or etc. The semiconductor chip 120 may be mounted on the interconnection substrate 110 by a flip-chip technique using solder bumps 125.

The molding member 130 may cover top and side surfaces of the semiconductor chip 120. Thus, the molding member 130 may prevent the side surface of the semiconductor chip 120 from being directly connected to the plurality of first lateral wires 210. Also, the molding member 130 may prevent the top surface of the semiconductor chip 120 from being directly connected to the metal layer 150.

Spaces between the side surface of the semiconductor chip 120 and the plurality of first lateral wires 210 may be filled up with the molding member 130. Also, the molding member 130 may enclose some or all of side surfaces of the plurality of first lateral wires 210. Thus, the plurality of first lateral wires 210 may be disposed in the molding member 130. In other words, the plurality of first lateral wires 210 may penetrate the molding member 130. The molding member 130 may be an epoxy molding compound (EMC).

The metal layer 150 may be electrically connected to the plurality of ground pads 111 by the plurality of first lateral wires 210. Thus, the metal layer 150 may have ground characteristics. The metal layer 150 may prevent emission of electromagnetic waves caused by the semiconductor chip 120 toward the top surface of the semiconductor chip 120. Also, the metal layer 150 may effectively emit heat generated by the semiconductor chip 120.

The metal layer 150 may be formed on the molding member 130. The metal layer 150 may be formed using a chemical vapor deposition (CVD) process, a physical vapor deposition (PVD) process, an atomic layer deposition (ALD) process, a screen printing process, an electroless plating process, or an electroplating process. The metal layer 150 may be formed using an Au or Ag pasting process.

The plurality of first lateral wires 210 may be electrically connected to the plurality of ground pads 111. Thus, the plurality of first lateral wires 210 may have ground characteristics. The plurality of first lateral wires 210 may enclose the side surface of the semiconductor chip 120. Thus, the plurality of first lateral wires 210 may prevent emission of electromagnetic waves caused by the semiconductor chip 120 in a lateral direction of the semiconductor chip 120.

Also, the plurality of first lateral wires 210 may transmit heat generated by the semiconductor chip 120 to the metal layer 150. Thus, the plurality of first lateral wires 210 may effectively help emission of heat generated by the semiconductor chip 120.

The plurality of first lateral wires 210 may be formed of a conductive material. For example, the plurality of first lateral wires 210 may include at least one of Au, Cu, Al, and an alloy thereof. The plurality of first lateral wires 210 may have a second diameter W2 of about 20 to 100 μm.

The plurality of first lateral wires 210 may penetrate the molding member 130. Thus, the plurality of first lateral wires 210 may have peaks P1 which are exposed in a top surface of the molding member 130. The peaks P1 exposed in the top surface of the molding member 130 may directly contact the metal layer 150.

The plurality of first lateral wires 210 may be bent from the interconnection substrate 110 toward the metal layer 150. Thus, a distance between two adjacent ones of the plurality of first lateral wires 210 may become different from the interconnection substrate 110 toward the metal layer 150. In other words, the distance between the two adjacent ones of the plurality of first lateral wires 210 may become smaller or greater from the interconnection substrate 110 toward the metal layer 150.

The bent direction of the plurality of first lateral wires 210 may be regularly repeated, respectively. Thus, two adjacent first lateral wires 210 bent toward each other may alternate with two adjacent first lateral wires 210 bent away from each other.

As a result, in the semiconductor package according to the first embodiment, the side surface of the semiconductor chip 120 may be enclosed by the plurality of first lateral wires 210. Also, the metal layer 150 may be disposed on the top surface of the semiconductor chip 120 and electrically connected to the plurality of first lateral wires 210. Thus, the semiconductor package may have an electromagnetic shielding structure using the plurality of first lateral wires 210 and the metal layer 150. Furthermore, the semiconductor package may have a heat radiation structure including the plurality of first lateral wires 210 and the metal layer 150.

### Embodiment 2

FIG. 3A is a partial plan view of a semiconductor package according to a second embodiment of the general inventive concept, and FIG. 3B is a longitudinal sectional view taken along line III-III′ of FIG. 3A.

Referring to FIGS. 3A and 3B, the semiconductor package according to the second embodiment may include an interconnection substrate 110, a semiconductor chip 120 mounted on a central region of the interconnection substrate 110, a plurality of ground pads 111 disposed on an outer region of the interconnection substrate 110, a molding member 130 configured to cover the semiconductor chip 120, and a metal layer 150 disposed on the molding member 130, and a plurality of second lateral wires 220 configured to electrically connect the plurality of ground pads 111 and the metal layer 150 and enclose a side surface of the semiconductor chip 120. Here, the plurality of ground pads 111 may be spaced a first distance d1 apart from one another.

In the semiconductor package according to the second embodiment, the interconnection substrate 110, the plurality of ground pads 111, the semiconductor chip 120, the molding member 130, the metal layer 150, and the plurality of second lateral wires 220 may be interpreted as including the same or similar components as disclosed in the first embodiment of the inventive concept. Thus, a detailed description of the respective components of the semiconductor package according to the second embodiment will be omitted.

According to the second embodiment, pairs of adjacent second lateral wires 220, each of which may be bent toward each other, may overlap one another and be repetitively disposed. Thus, a pair of second lateral wires 220 bent far away from each other may be bonded to the same ground pad 111.

### Embodiments 3 Through 7

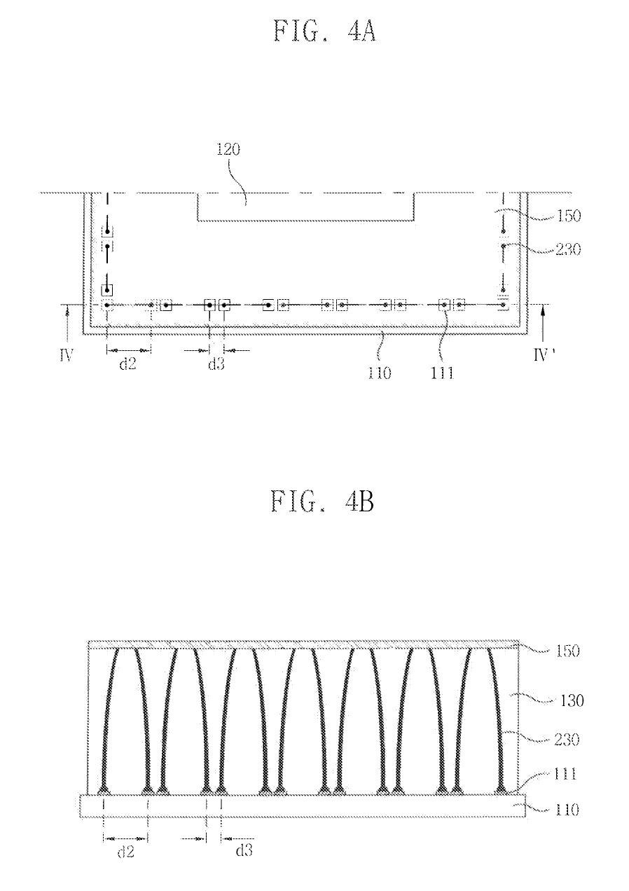

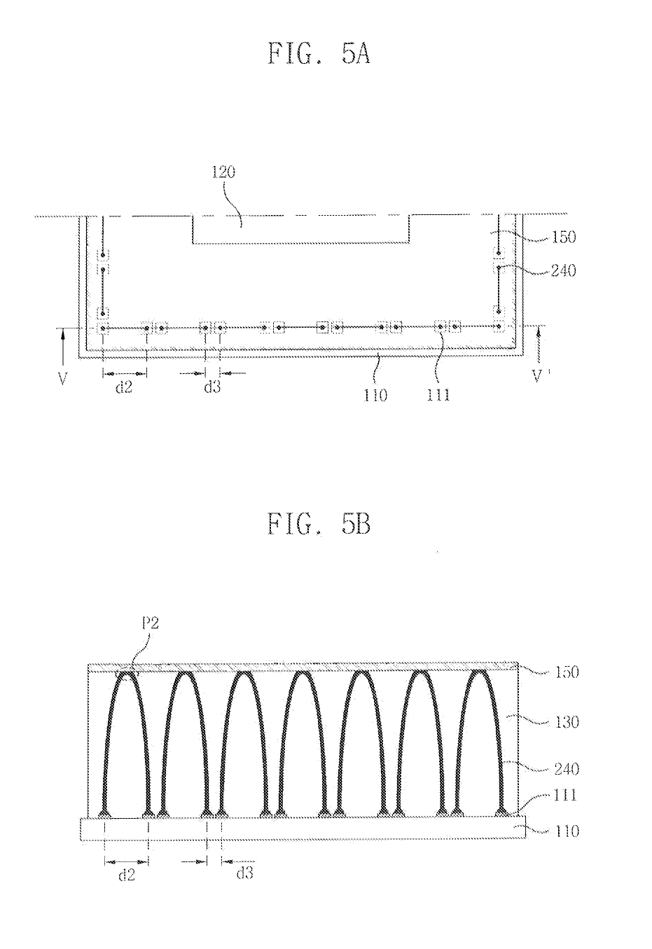

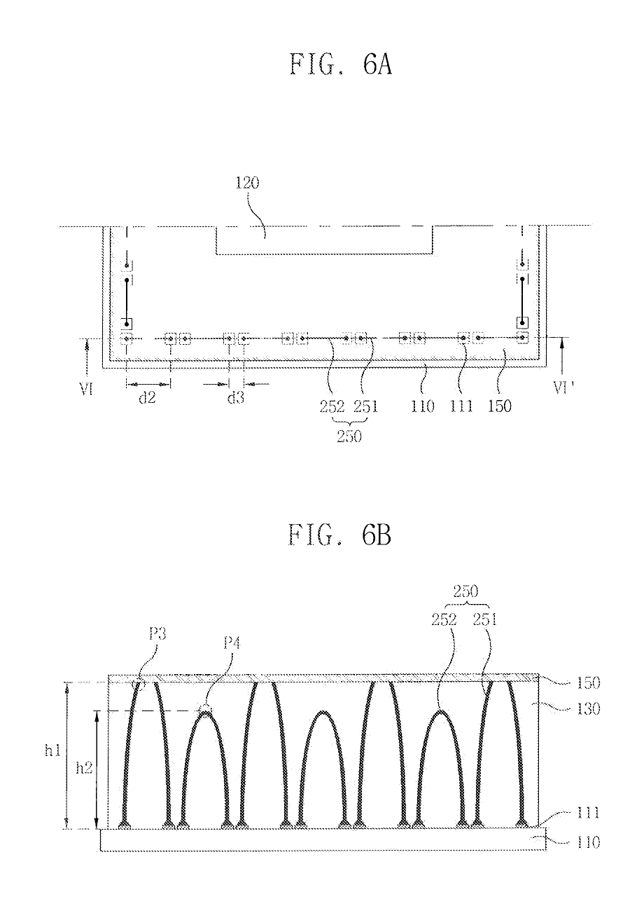

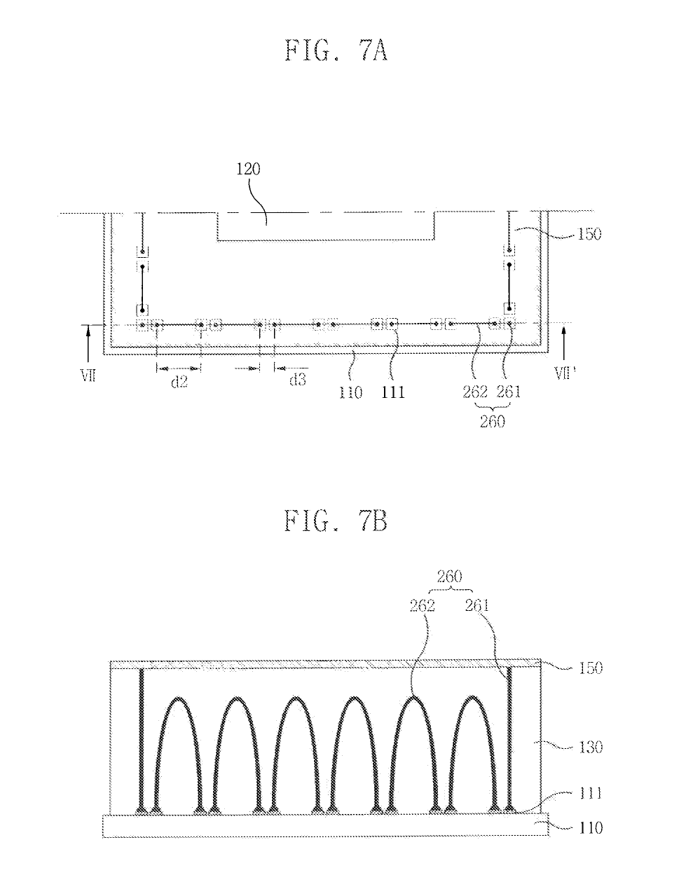

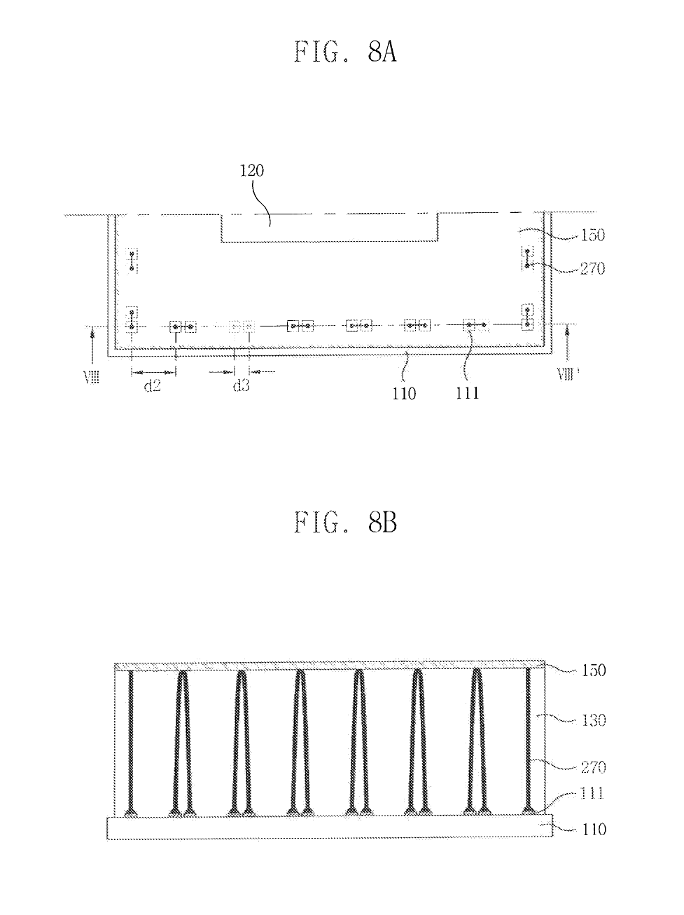

FIGS. 4A through 8A are partial plan views of semiconductor packages according to third to seventh embodiments of the general inventive concept. FIG. 4B is a longitudinal sectional view taken along line IV-IV′ of FIG. 4A. FIG. 5B is a longitudinal sectional view taken along line V-V′ of FIG. 5A. FIG. 6B is a longitudinal sectional view taken along line VI-VI′ of FIG. 6A. FIG. 7B is a longitudinal sectional view taken along line VII-VII′ of FIG. 7A. Also, FIG. 8B is a longitudinal sectional view taken along line VIII-VIII′ of FIG. 8A.

Referring to FIGS. 4A through 8B, each of the semiconductor packages according to the third through seventh embodiments of the general inventive concept may include an interconnection substrate 110, a semiconductor chip 120 mounted on a central region of the interconnection substrate 110, a plurality of ground pads 111 disposed on an outer region of the interconnection substrate 110, a molding member 130 configured to cover the semiconductor chip 120, a metal layer 150 disposed on the molding member 130, and a plurality of lateral wires 230, 240, 250, 260, or 270 configured to electrically connect the plurality of ground pads 111 and the metal layer 150 and enclose a side surface of the semiconductor chip 120.

Ground pads 111 disposed a second distance d2 apart from one another may regularly or irregularly alternate with ground pads 111 disposed a third distance d3 apart from one another. Here, the second distance d2 may be greater than the third distance d3 and equal to the first distance d1 disclosed in the first embodiment of the general inventive concept.

In the semiconductor packages according to the third through seventh embodiments of the general inventive concept, the interconnection substrate 110, the plurality of ground pads 111, the semiconductor chip 120, the molding member 130, the metal layer 150, and the plurality of lateral wires 230, 240, 250, 260, or 270, may be interpreted as including the same or similar components as described in other embodiments of the general inventive concept. Thus, a detailed description of the respective components of the semiconductor package according to the third through seventh embodiments will be omitted.

Referring to FIG. 4B, in the semiconductor package according to the third embodiment, the plurality of third lateral wires 230, which may be bent toward one another, may be bonded to the plurality of ground pads 111 spaced the second distance d2 apart from one another. Thus, the plurality of third lateral wires 230, which may be bent away from one another, may be bonded to the plurality of ground pads 111 spaced the third distance d3 apart from one another.

Thus, two adjacent third lateral wires 230, which may be bent toward each other and spaced the second distance d2 apart from each other, and two adjacent third lateral wires 230, which may be bent away from each other and spaced the third distance d3 apart from each other, may be repetitively bonded to the plurality of ground pads 111.

Referring to FIG. 5B, in the semiconductor package according to the fourth embodiment, two adjacent ground pads 111 spaced the second distance d2 apart from each other may be directly connected to each other by the corresponding one of the fourth lateral wires 240. Thus, the plurality of fourth lateral wires 240 may have loops with a predetermined height along the outline of the interconnection substrate 110. That is, the plurality of fourth lateral wires 240 may have an arch shape with a peak P2. The peaks P2 of the plurality of fourth lateral wires 240 may be exposed to the metal layer 150.

The plurality of fourth lateral wires 240, which may be bent away from one another, may be bonded to two adjacent ones of the ground pads 111 spaced the third distance d3 apart from one another. Thus, two adjacent ground pads 111 spaced the third distance d3 apart from each other may not be directly connected to each other by the plurality of fourth lateral wires 240.

Referring to FIG. 6B, in the semiconductor package according to the fifth embodiment, the plurality of fifth lateral wires 250 may include at least one sixth lateral wire 251 having a peak P3 exposed in a top surface of the molding member 130 and at least one seventh lateral wire 252 having a peak P4 covered with the molding member 130. Here, the at least one sixth lateral wire 251 may directly connect the plurality of ground pads 111 and the metal layer 150.

The at least one sixth lateral wire 251 may be bent toward each other from two adjacent ground pads 111 spaced the second distance d2 apart from each other. The at least one seventh lateral wire 252 may directly connect the two adjacent ground pads 111 spaced the second distance d2 apart from each other. Thus, a pair of sixth lateral wires 251 may be bent toward each other and bonded to each other between the two adjacent seventh lateral wires 252.

The at least one seventh lateral wire 252 may have a loop with a height h2 lower than the first height h1 of the peak P3 of the at least one sixth lateral wire 251 along the edge of the interconnection substrate 110. In other words, the at least one seventh lateral wire 252 may have an arch shape with the second height h2 lower than the first height h1.

Referring to FIG. 7B, in the semiconductor package according to the sixth embodiment, the plurality of eighth lateral wires 260 may include at least one ninth lateral wire 261 and at least one tenth lateral wire 262. The at least one ninth lateral wire 261 may connect the plurality of ground pads 111 and the metal layer 150 by the shortest route. The at least one tenth lateral wire 262 may directly connect two adjacent ground pads 111 spaced the second distance d2 apart from each other.

The at least one ninth lateral wire 261 may be directly in contact with the metal layer 150. The at least one ninth lateral wire 261 may be spaced the third distance d3 apart from the plurality of ground pads 111 bonded to the at least one tenth lateral wire 262.

Two adjacent ones of the tenth lateral wires 262 may be spaced the third distance d3 apart from each other. The at least one tenth lateral wire 262 may have a loop with a lower height than the molding member 130.

The at least one ninth lateral wire 261 may be disposed on a corner region of the interconnection substrate 110. Thus, a plurality of tenth lateral wires 262 may be disposed between two adjacent ninth lateral wires 261.

Referring to FIG. 8B, in the semiconductor package according to the seventh embodiment, two adjacent ground pads 111 spaced the third distance d3 apart from each other may be directly connected to each other by the corresponding one of the eleventh lateral wires 270. Thus, the plurality of eleventh lateral wires 270 may have loops with a predetermined height along the outline of the interconnection substrate 110. That is, the plurality of eleventh lateral wires 270 may have an arch shape.

The peaks of the plurality of eleventh lateral wires 270 may be exposed to the metal layer 150 to electrically connect the metal layer 150 and the ground pads 111.

The plurality of eleventh lateral wires 270, which may be bent away from one another, may be bonded to two adjacent ground pads 111 spaced the second distance d2 apart from one another. Thus, two adjacent ground pads 111 spaced the second distance d2 apart from each other may not be directly connected to each other by the plurality of eleventh lateral wires 270.

The third distance d3 may be smaller than the second distance d2.

### Embodiments 8 and 9

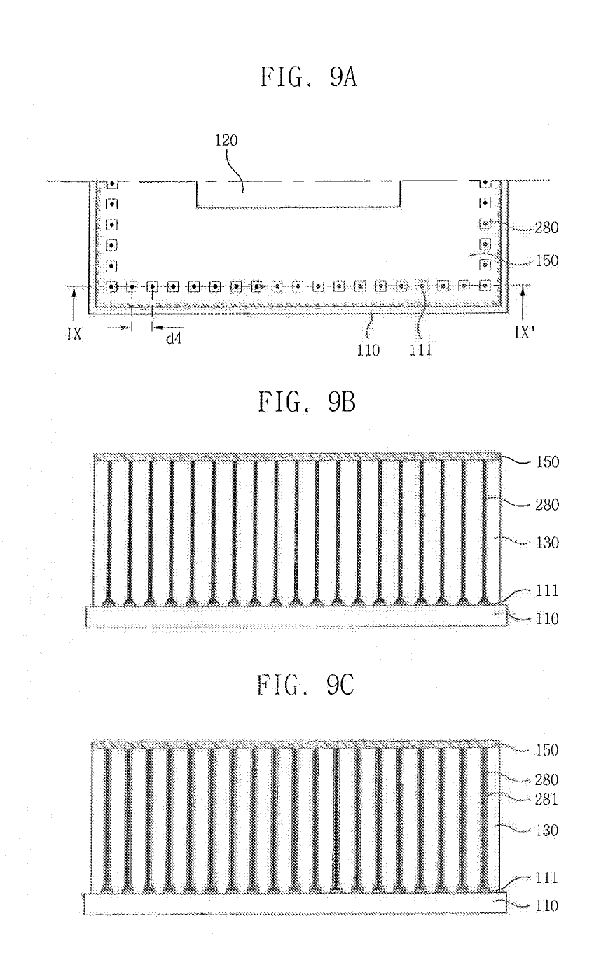

FIG. 9A is a partial plan view of a semiconductor package according to eighth and ninth embodiments of the general inventive concept. FIG. 9B is a longitudinal sectional view taken along line IX-IX′ of FIG. 9A, which illustrates the semiconductor package according to the eighth embodiment of the general inventive concept, and FIG. 9C is a longitudinal sectional view taken along line IX-IX′ of FIG. 9A, which illustrates the semiconductor package according to the ninth embodiment of the general inventive concept.

Referring to FIGS. 9A through 9C, each of the semiconductor packages according to the eighth and ninth embodiments of the inventive concept may include an interconnection substrate 110, a semiconductor chip 120 mounted on a central region of the interconnection substrate 110, a plurality of ground pads 111 disposed on an outer region of the interconnection substrate 110, a molding member 130 configured to cover the semiconductor chip 120, a metal layer 150 disposed on the molding member 130, and a plurality of fourteenth lateral wires 280 configured to electrically connect the plurality of ground pads 111 and the metal layer 150 and enclose a side surface of the semiconductor chip 120. Here, the plurality of ground pads 111 may be spaced a fourth distance d4 apart from one another.

In the semiconductor packages according to the eighth and ninth embodiments, the interconnection substrate 110, the plurality of ground pads 111, the semiconductor chip 120, the molding member 130, the metal layer 150, and the plurality of fourteenth lateral wires 280 may be interpreted as including the same or similar components as disclosed in other embodiments of the general inventive concept. Thus, a detailed description of the respective components of the semiconductor packages according to the eighth and ninth embodiments will be omitted.

Referring to FIGS. 9A and 9B, in the semiconductor package according to the eighth embodiment, the plurality of fourteenth lateral wires 280 may connect the plurality of ground pads 111 and the metal layer 150 by the shortest route. The plurality of fourteenth lateral wires 280 may vertically penetrate the molding member 130. For example, each of the plurality of fourteenth lateral wires 280 may have a pillar shape. The fourth distance d4 may be shorter than the first distance d1 disclosed in the first embodiment.

Referring to FIGS. 9A and 9C, the semiconductor package according to the ninth embodiment may further include surface wires 281 disposed on the surfaces of the plurality of fourteenth lateral wires 280. The surface wires 281 may prevent physical deformation of the plurality of fourteenth lateral wires 280. Thus, the physical stability of the plurality of fourteenth lateral wires 280 may be improved. Also, the electrical stability of the plurality of fourteenth lateral wires 280 may be improved.

The surface wires 281 may be formed of the same material as the plurality of fourteenth lateral wires 280. The surface wires 281 may include a plating layer configured to enclose the surfaces of the plurality of fourteenth lateral wires 280.

### Embodiment 10

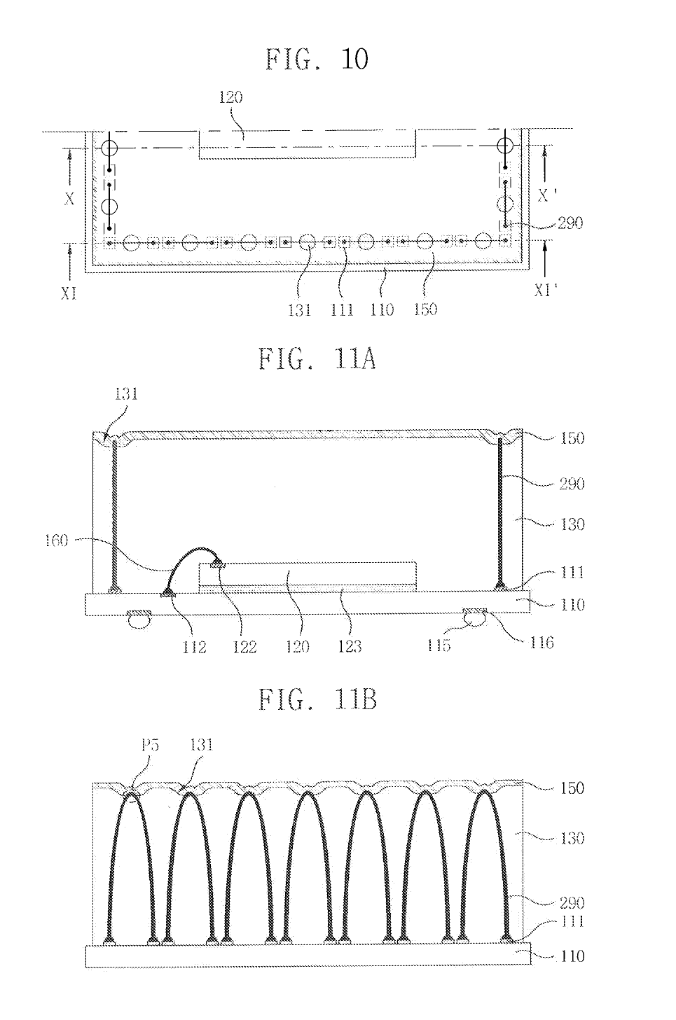

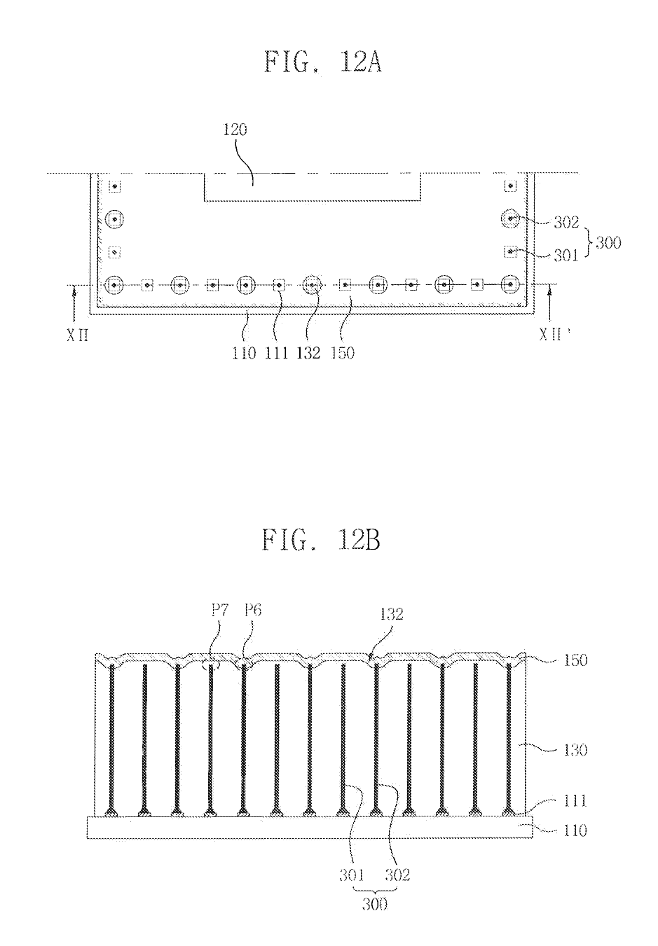

FIG. 10 is a partial plan view of a semiconductor package according to a tenth embodiment of the general inventive concept. FIG. 11A is a longitudinal sectional view taken along line X-X′ of FIG. 10, and FIG. 11B is a longitudinal sectional view taken along line XI-XI′ of FIG. 10.

Referring to FIGS. 10, 11A, and 11B, the semiconductor package according to the tenth embodiment of the general inventive concept may include an interconnection substrate 110, a semiconductor chip 120 mounted on a central region of the interconnection substrate 110, a plurality of ground pads 111 disposed on an outer region of the interconnection substrate 110, a molding member 130 configured to cover the semiconductor chip 120, a metal layer 150 disposed on the molding member 130, and a plurality of fifteenth lateral wires 290 configured to electrically connect the plurality of ground pads 111 and the metal layer 150 and enclose a side surface of the semiconductor chip 120.

In the semiconductor package according to the tenth embodiment, the interconnection substrate 110, the plurality of ground pads 111, the semiconductor chip 120, the molding member 130, the metal layer 150, and the plurality of fifteenth lateral wires 290 may be interpreted as including the same or similar components as disclosed in other embodiments of the general inventive concept. Thus, a detailed description of the respective components of the semiconductor package according to the tenth embodiment will be omitted.

In the semiconductor package according to the tenth embodiment, the semiconductor chip 120 may be mounted on the interconnection substrate 110 using a wire bonding technique. To this end, the semiconductor package according to the tenth embodiment may include a signal pad 112 disposed on the interconnection substrate 110. Also, a chip pad 122 may be formed on a top surface of the semiconductor chip 120.

The semiconductor chip 120 may be bonded to a top surface of the interconnection substrate 110 using an adhesive layer 123. The adhesive layer 123 may be a die-attach film (DAF). The DAF may be formed using a liquid or film-type epoxy resin.

The signal pad 112 may be formed of a conductive material. For example, the signal pad 112 may include at least one selected from the group including Au, Ag, Cu, Ni, Al, Sn, Pb, Pt, Bi, In, and an alloy thereof.

The signal pad 112 may be disposed between the semiconductor chip 120 and the plurality of ground pads 111. The signal pad 112 may be electrically connected to the chip pad 122 by signal wire 160. The signal wire 160 may be formed of the same material as the plurality of fifteenth lateral wires 290.

The chip pad 122 may be formed of a similar conductive material to the signal pad 112. In the semiconductor package according to the tenth embodiment, it is illustrated that the chip pad 122 is buried in the top surface of the semiconductor chip 120. However, in the semiconductor package according to the tenth embodiment, the chip pad 122 may partially or wholly protrude from the top surface of the semiconductor chip 120.

The plurality of fifteenth lateral wires 290 may directly connect two adjacent ones of the plurality of ground pads 111. Thus, the plurality of fifteenth lateral wires 290 may have loops with the same height. Here, peaks P5 of the loops of the plurality of fifteenth lateral wires 290 may be covered with the molding member 130.

The molding member 130 may include a plurality of first grooves 131 to expose the peaks P5 of the plurality of fifteenth lateral wires 290. Here, the peaks P5 exposed by the plurality of first grooves 131 may be directly in contact with the metal layer 150.

### Embodiment 11

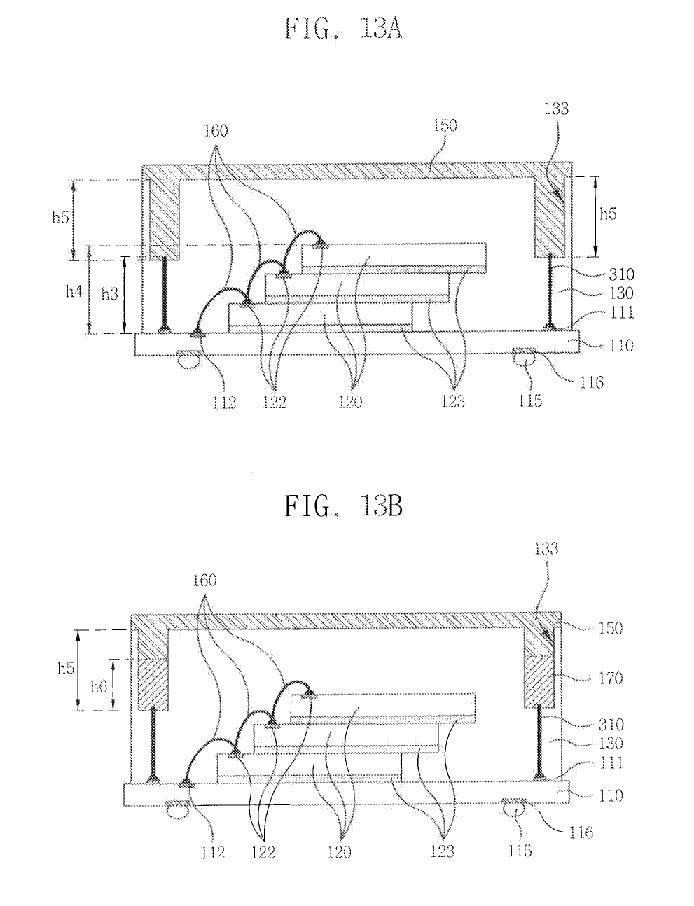

FIG. 12A is a partial plan view of a semiconductor package according to an eleventh embodiment of the general inventive concept, and FIG. 12B is a longitudinal sectional view taken along line XII-XII′ of FIG. 12A.

Referring to FIGS. 12A and 12B, the semiconductor package according to the eleventh embodiment may include an interconnection substrate 110, a semiconductor chip 120 mounted on a central region of the interconnection substrate 110, a plurality of ground pads 111 disposed on an outer region of the interconnection substrate 110, a molding member 130 configured to cover the semiconductor chip 120, a metal layer 150 disposed on the molding member 130, and a plurality of sixteenth lateral wires 300 configured to electrically connect the plurality of ground pads 111 and the metal layer 150 and enclose a side surface of the semiconductor chip 120.

In the semiconductor package according to the eleventh embodiment, the interconnection substrate 110, the plurality of ground pads 111, the semiconductor chip 120, the molding member 130, the metal layer 150, and the plurality of sixteenth lateral wires 300 may be interpreted as including the same or similar components as disclosed in other embodiments of the general inventive concept. Thus, a detailed description of the respective components of the semiconductor package according to the eleventh embodiment will be omitted.

The plurality of sixteenth lateral wires 300 may include a plurality of seventeenth lateral wires 301 and a plurality of eighteenth lateral wires 302. The plurality of eighteenth lateral wires 302 may connect the corresponding ground pads 111 and the metal layer 150 by the shortest route. In the semiconductor package according to the eleventh embodiment, the plurality of ground pads 111 may be spaced the same distance or a regular distance apart from one another. However, in the semiconductor package according to the eleventh embodiment, the plurality of ground pads 111 may be spaced various distances apart from one another. For example, in the semiconductor package according to the eleventh embodiment, ground pads 111 spaced a relatively small distance apart from one another may alternate with ground pads 111 spaced a relatively great distance apart from one another.

The molding member 130 may include at least one second groove 132 by which at least one peak P6 of the plurality of eighteenth lateral wires 302 may be exposed. That is, the plurality of sixteenth lateral wires 300 may include at least one eighteenth lateral wire 302 whose peak P6 is exposed by the at least one second groove 132 formed in the top surface of the molding member 130 and at least one seventeenth lateral wire 301 whose peak P7 is covered with the molding member 130.

### Embodiments 12 Through 14

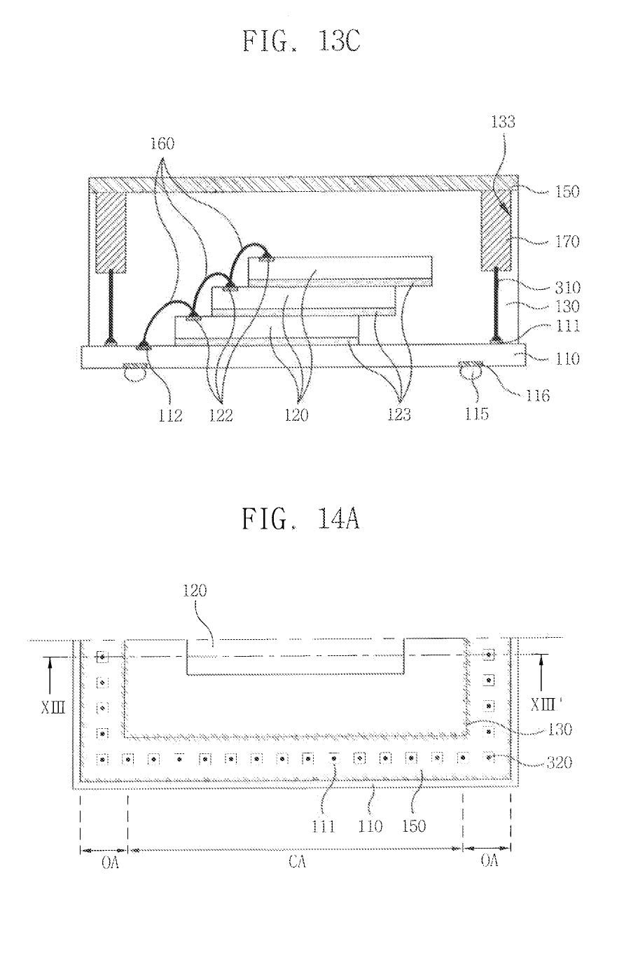

FIGS. 13A through 130 are longitudinal sectional views of semiconductor packages according to twelfth through fourteenth embodiments of the general inventive concept.

Referring to FIGS. 13A through 13C, each of the semiconductor packages according to the twelfth through fourteenth embodiments may include an interconnection substrate 110, a plurality of semiconductor chips 120 mounted on a central region of the interconnection substrate 110, a plurality of ground pads 111 disposed on an outer region of the interconnection substrate 110, a molding member 130 configured to cover the plurality of semiconductor chips 120, a metal layer 150 disposed on the molding member 130, and a plurality of nineteenth lateral wires 310 configured to electrically connect the plurality of ground pads 111 and the metal layer 150 and enclose side surfaces of the plurality of semiconductor chips 120.

Here, the plurality of nineteenth lateral wires 310 may have a third height h3. The third height h3 may be lower than a fourth height h4 by which the plurality of semiconductor chips 120 may be stacked.

In the semiconductor packages according to the twelfth through fourteenth embodiments, the interconnection substrate 110, the plurality of ground pads 111, the semiconductor chip 120, the molding member 130, the metal layer 150, and the plurality of nineteenth lateral wires 310 may be interpreted as including the same or similar components as disclosed in other embodiments of the general inventive concept. Thus, a detailed description of the respective components of the semiconductor packages according to the twelfth through fourteenth embodiments will be omitted.

Referring to FIG. 13A, in the semiconductor package according to the twelfth embodiment, the plurality of semiconductor chips 120 may be stacked on the interconnection substrate 110 using adhesive layers 123. The plurality of semiconductor chips 120 may be electrically connected to the interconnection substrate 110 by a plurality of signal wires 160. To this end, the interconnection substrate 110 may include a signal pad 112. Also, chip pads 122 may be formed on top surfaces of the plurality of semiconductor chips 120 and connected to the signal pad 112 by the plurality of signal wires 160.

In this case, in the semiconductor package according to the twelfth embodiment, the signal pad 112, the chip pads 122, and the plurality of signal wires 160 may be interpreted as including the same or similar components as disclosed in the tenth embodiment. Thus, a detailed description of the respective components of the semiconductor package according to the twelfth embodiment will be understood with reference to the tenth embodiment.

Furthermore, in the semiconductor package according to the twelfth embodiment, it is illustrated that the interconnection substrate 110 includes one signal pad 112. However, in the semiconductor package according to the twelfth embodiment, the interconnection substrate 110 may include a plurality of signal pads 112.

The molding member 130 may include at least one third groove 133 by which peaks of the plurality of nineteenth lateral wires 310 are exposed. The at least one third groove 133 may have a fifth height h5 greater than a distance between a top surface of the molding member 130 and a top surface of the plurality of semiconductor chips 120.

Referring to FIG. 13B, the semiconductor package according to the thirteenth embodiment may further include a solder material 170 configured to partially fill the at least one third groove 133 formed in the molding member 130. The solder material 170 may have a sixth height h6 lower than the fifth height h5 of the at least one third groove 133.

Referring to FIG. 130, in the semiconductor package according to the fourteenth embodiment, the solder material 170 may completely fill the at least one third groove 133. In the fourteenth embodiment, it is illustrated that the solder material 170 forms a planar top surface with the molding member 130. However, in the fourteenth embodiment, the top surface of the solder material 170 may be higher than that of the molding member 130.

### Embodiment 15

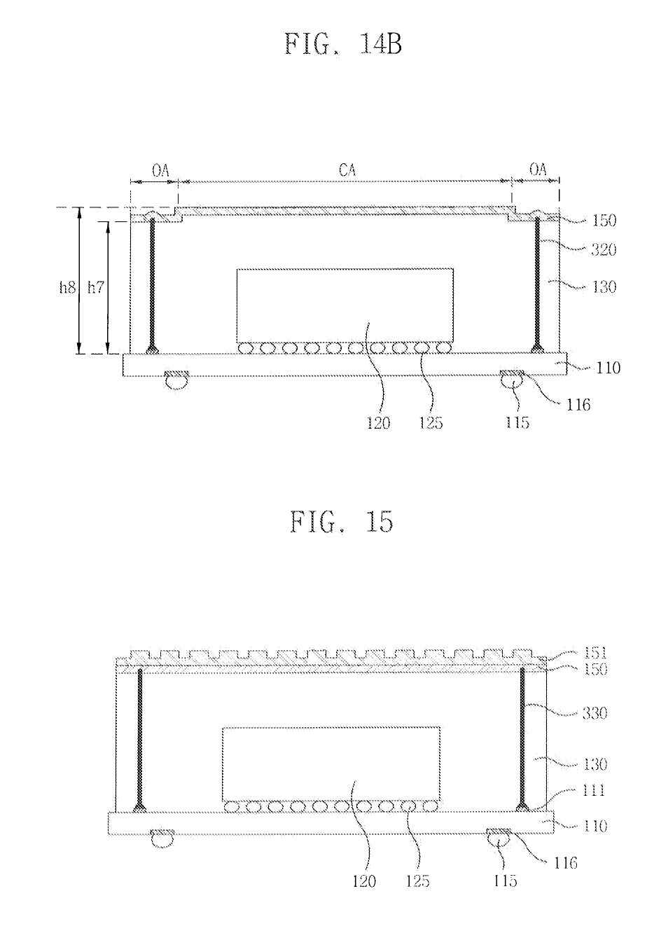

FIG. 14A is a partial plan view of a semiconductor package according to a fifteenth embodiment of the general inventive concept, and FIG. 14B is a longitudinal sectional view taken along line XIII-XIII′ of FIG. 14A.

Referring to FIGS. 14A and 14B, the semiconductor package according to the fifteenth embodiment of the general inventive concept may include an interconnection substrate 110 including a first region CA and a second region OA disposed outside the first region CA, a semiconductor chip 120 mounted on the first region CA of the interconnection substrate 110, a plurality of ground pads 111 disposed on the second region OA of the interconnection substrate 110, a molding member 130 configured to cover the semiconductor chip 120, a metal layer 150 disposed on the molding member 130, and a plurality of twentieth lateral wires 320 configured to electrically connect the plurality of ground pads 111 and the metal layer 150 and enclose side surfaces of the plurality of semiconductor chips 120.

In the semiconductor package according to the fifteenth embodiment, the interconnection substrate 110, the plurality of ground pads 111, the semiconductor chip 120, the molding member 130, the metal layer 150, and the plurality of twentieth lateral wires 320 may be interpreted as including the same or similar components as disclosed in other embodiments of the general inventive concept. Thus, a detailed description of the respective components of the semiconductor package according to the fifteenth embodiment will be omitted.

A region of the molding member 130 corresponding to the second region OA may have a seventh height h7 lower than an eighth height h8 of a region of the molding member 130 corresponding to the first region CA. The seventh height h7 may be a height by which peaks of the plurality of twentieth lateral wires 320 are exposed. Thus, the peaks of the plurality of twentieth lateral wires 320 may be exposed in a top surface of the molding member 130 in the second region OA.

### Embodiment 16

FIG. 15 is a longitudinal sectional view of a semiconductor package according to a sixteenth embodiment of the general inventive concept.

Referring to FIG. 15, the semiconductor package according to the sixteenth embodiment may include an interconnection substrate 110, a semiconductor chip 120 mounted on a central region of the interconnection substrate 110 using solder bumps 125, a plurality of ground pads 111 disposed on an outer region of the interconnection substrate 110, a molding member 130 configured to cover the semiconductor chip 120, a metal layer 150 disposed on the molding member 130, a heat dissipation member 151 disposed on the metal layer 150, and a plurality of twenty-first lateral wires 330 configured to electrically connect the plurality of ground pads 111 and the metal layer 150 and enclose side surfaces of the plurality of semiconductor chips 120.

In the semiconductor package according to the sixteenth embodiment, the interconnection substrate 110, the plurality of ground pads 111, the semiconductor chip 120, the molding member 130, the metal layer 150, and the plurality of twenty-first lateral wires 330 may be interpreted as including the same or similar components as disclosed in other embodiments of the general inventive concept. Thus, a detailed description of the respective components of the semiconductor package according to the sixteenth embodiment will be omitted.

The heat dissipation member 151 may have such a shape as to effectively dissipate heat. For example, the heat dissipation member 151 may have a rough top surface. Thus, the heat dissipation member 151 may easily dissipate heat transmitted to the metal layer 150.

The heat dissipation member 151 may be formed of the same material as the metal layer 150. Thus, the heat dissipation member 151 may be integrally formed with the metal layer 150.

In the sixteenth embodiment, it is illustrated that the heat dissipation member 151 is disposed on the metal layer 150. However, in the semiconductor package according to the sixteenth embodiment, the heat dissipation member 151 may be disposed between the metal layer 150 and the molding member 130.

### Embodiment 17

FIG. 16 is a longitudinal sectional view of a semiconductor package according to a seventeenth embodiment of the general inventive concept.

Referring to FIG. 16, the semiconductor package according to the seventeenth embodiment may include an interconnection substrate 110, a semiconductor chip 120 mounted on a central region of the interconnection substrate 110 using solder bumps 125, a plurality of ground pads 111 disposed on an outer region of the interconnection substrate 110, a molding member 130 configured to cover the semiconductor chip 120, a metal layer 150 disposed on the molding member 130, and a plurality of twenty-second lateral wires 340 configured to electrically connect the plurality of ground pads 111 and the metal layer 150 and enclose side surfaces of the plurality of semiconductor chips 120.

In the semiconductor package according to the seventeenth embodiment, the interconnection substrate 110, the plurality of ground pads 111, the semiconductor chip 120, the molding member 130, the metal layer 150, and the plurality of twenty-second lateral wires 340 may be interpreted as including the same or similar components as disclosed in other embodiments of the general inventive concept. Thus, a detailed description of the respective components of the semiconductor package according to the seventeenth embodiment will be omitted.

A plurality of ground via holes 113 may be formed inside the interconnection substrate 110. The plurality of ground via holes 113 may be electrically connected to the plurality of ground pads 111. Thus, the plurality of ground via holes 113 may have ground characteristics. Thus, the plurality of ground via holes 113 may prevent emission of electromagnetic waves in a lateral direction of the interconnection substrate 110. Also, the plurality of ground via holes 113 may effectively help emission of heat transmitted from the semiconductor chip 120.

### Embodiments 18 Through 24

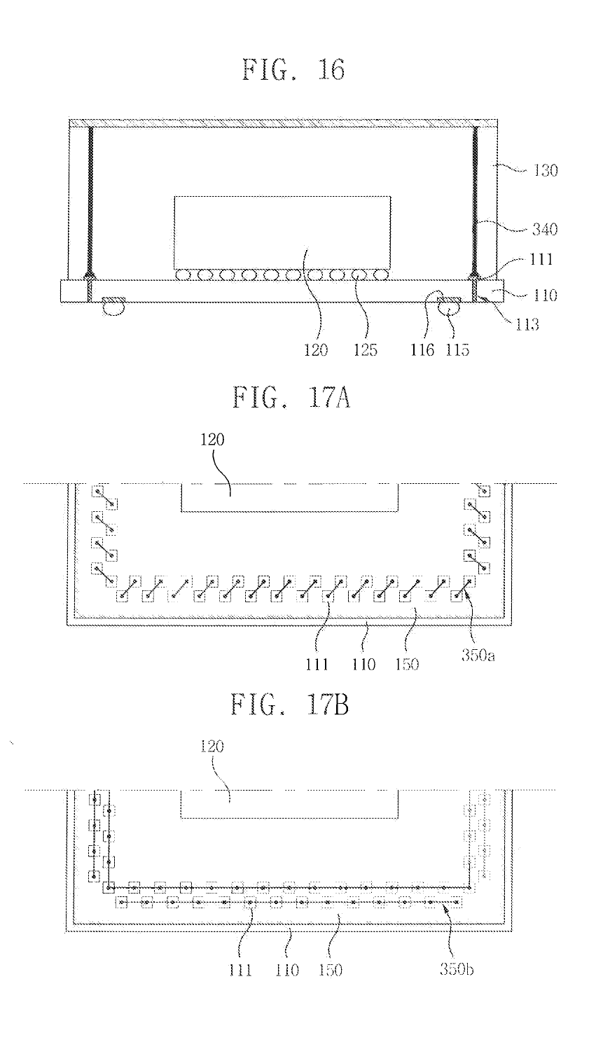

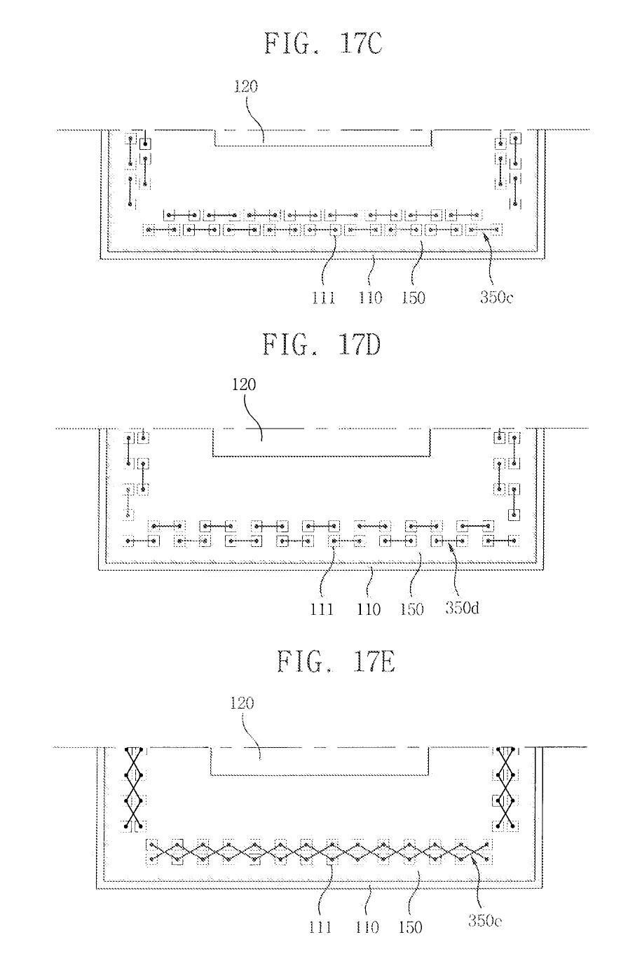

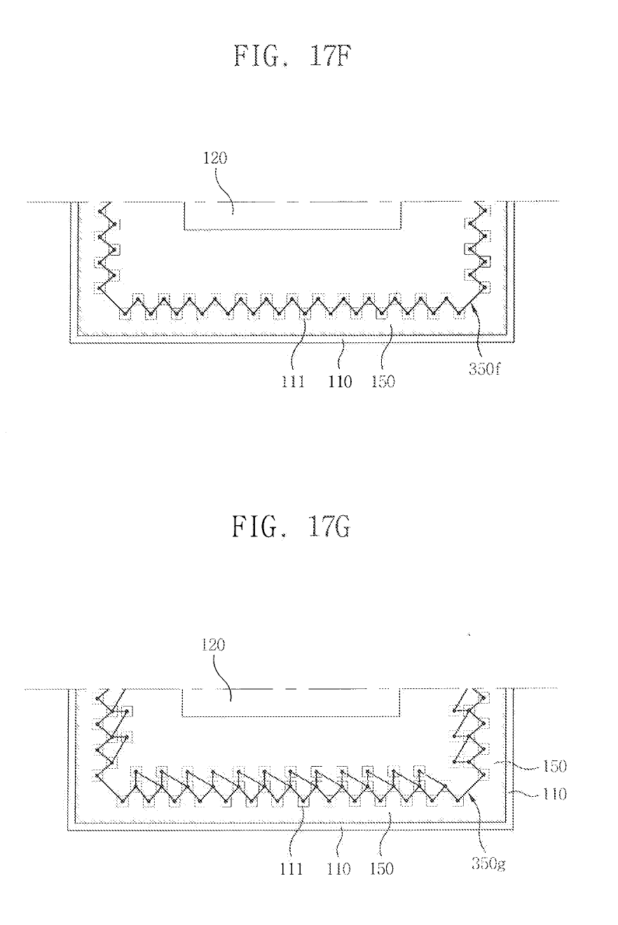

FIGS. 17A through 17G are partial plan views of semiconductor packages according to eighteenth through twenty-fourth embodiments of the general inventive concept.

Referring to FIGS. 17A through 17G, each of the semiconductor packages according to the eighteenth through twenty-fourth embodiments may include an interconnection substrate 110, a semiconductor chip 120 mounted on a central region of the interconnection substrate 110, a plurality of ground pads 111 disposed on an outer region of the interconnection substrate 110, a molding member (not shown) configured to cover the semiconductor chip 120, a metal layer 150 disposed on the molding member, and a plurality of lateral wires, for example, twenty-third through twenty-ninth lateral wires 350a to 350g configured to electrically connect the plurality of ground pads 111 and the metal layer 150 and enclose lateral wires of the plurality of semiconductor chips 120.

In the semiconductor packages according to the eighteenth through twenty-fourth embodiments, the interconnection substrate 110, the plurality of ground pads 111, the semiconductor chip 120, the molding member 130, the metal layer 150, and the twenty-third through twenty-ninth lateral wires 350a to 350g may be interpreted as including the same or similar components as disclosed in other embodiments of the general inventive concept. Thus, a detailed description of the respective components of the semiconductor packages according to the eighteenth through twenty-fourth embodiments will be omitted.

The plurality of ground pads 111 may be formed in a plurality of columns along the outer region of the interconnection substrate 110. The plurality of ground pads 111 may be formed in two adjacent columns. For example, the plurality of ground pads 111 may be formed in a lattice shape. Alternatively, the plurality of ground pads 111 may be formed zigzag in two adjacent columns.

The plurality of twenty-third through twenty-ninth lateral wires 350a to 350g may directly connect two adjacent columns of ground pads 111 out of the plurality of ground pads 111.

Referring to FIG. 17A, in the semiconductor package according to the eighteenth embodiment, the plurality of twenty-third lateral wires 350a may discretely and directly connect the plurality of ground pads 111 formed zigzag in the two adjacent columns. Thus, the plurality of twenty-third lateral wires 350a may be inclined at an angle with a side surface of the interconnection substrate 110.

Referring to FIG. 17B, in the semiconductor package according to the ninth embodiment, the plurality of twenty-fourth lateral wires 350b may continuously and directly connect the plurality of ground pads 111 arranged in the same column. Thus, the plurality of twenty-fourth lateral wires 350b may connect the plurality of ground pads 111 arranged in a column.

Referring to FIG. 170, in the semiconductor package according to the twentieth embodiment, the plurality of twenty-fifth lateral wires 350c may discontinuously and directly connect the plurality of ground pads 111 arranged in the same column.

Here, the plurality of ground pads 111 may be spaced irregular distances apart from one another. For example, ground pads 111 spaced a relatively large distance apart from one another may regularly or irregularly alternate with ground pads 111 spaced a relatively small distance apart from one another. Two ground pads 111 spaced the relatively small distance apart from each other may be interposed between two ground pads 111 spaced the relatively large distance apart from each other.

Referring to FIG. 17D, in the semiconductor package according to the twenty-first embodiment, the plurality of twenty-sixth lateral wires 350d may discontinuously directly connect the plurality of ground pads 111 arranged in the same column. Here, the plurality of ground pads 111 may be arranged in a lattice shape.

Thus, the plurality of twenty-sixth lateral wires 350d configured to directly connect two adjacent ground pads 111 may be disposed zigzag in two adjacent columns.

Referring to FIG. 17E, in the semiconductor package according to the twenty-second embodiment, the plurality of twenty-seventh lateral wires 350e may directly connect two adjacent columns of ground pads 111 in a mesh or cross shape.

Referring to FIG. 17F, in the semiconductor package according to the twenty-third embodiment, the plurality of twenty-eighth lateral wires 350f may directly connect two adjacent columns of ground pads 111 in a zigzag shape.

Referring to FIG. 17G, in the semiconductor package according to the twenty-fourth embodiment, the plurality of twenty-ninth lateral wires 350g may connect two adjacent columns of around pads in different shapes. The plurality of twenty-ninth lateral wires 350g may connect the plurality of ground pads 111 in various shapes according to combinations of methods according to the embodiments of the general inventive concept.

Here, the plurality of ground pads 111 may be arranged in the plurality of columns in different manners. For example, two adjacent columns of ground pads 111 may be arranged parallel to one another, and a column of ground pads 111 disposed inside the two adjacent columns of ground pads 111 may be arranged to be zigzag with respect to the two adjacent columns of ground pads 111.

### Method Embodiment 1

FIGS. 18A, 19A, 20A, 21A, 22A, and 23A are longitudinal sectional views taken along line I-I′ of FIG. 1, which illustrate a first method of fabricating a semiconductor package according to embodiments of the general inventive concept, and FIGS. 18B, 19B, 20B, 21B, 22B, and 23B are longitudinal sectional views taken along line II-II′ of FIG. 1, which illustrate the first method.

The first method of fabricating the semiconductor package according to the embodiments of the general inventive concept will now be described with reference to FIGS. 18A through 23B. To begin with, as shown in FIGS. 18A and 18B, the first method of fabricating the semiconductor package according to the embodiments of the general inventive concept may include preparing an interconnection substrate 110 having an outer region on which a plurality of ground pads 111 are formed. Here, the plurality of ground pads 111 may be formed along the outline of the interconnection substrate 110 to enclose a central region of the interconnection substrate 110.

The interconnection substrate 110 may include a PCB, an LF, a tape interconnection, or a ceramic substrate. The interconnection substrate 110 may include a plurality of conductive lands 116 disposed in a bottom surface thereof and a plurality of conductive bumps 115 bonded to the plurality of conductive lands 116.

The plurality of conductive lands 116 and the plurality of conductive bumps 115 may electrically connect the semiconductor package according to the embodiment of the general inventive concept with a module board (not shown) or a main circuit board (not shown). The plurality of conductive lands 116 and the plurality of conductive bumps 115 may include at least one selected from the group including Au, Ag, Cu, Ni, Al, Sn, Pb, Pt, Bi, In, and an alloy thereof. In this case, the plurality of conductive bumps 115 may include a solder material. The solder material may be Sn.

Two adjacent ones of the plurality of ground pads 111 may be formed a first distance d1 apart from each other. The first distance d1 may be such a distance as to shield electromagnetic waves caused by the semiconductor chip 120. For example, the first distance d1 may range from 50 to 100 μm.

The plurality of ground pads 111 may be formed of a conductive material. For example, the plurality of ground pads 111 may include at least one selected from the group including Au, Ag, Cu, Ni, Al, Sn, Pb, Pt, Bi, In, and an alloy thereof.

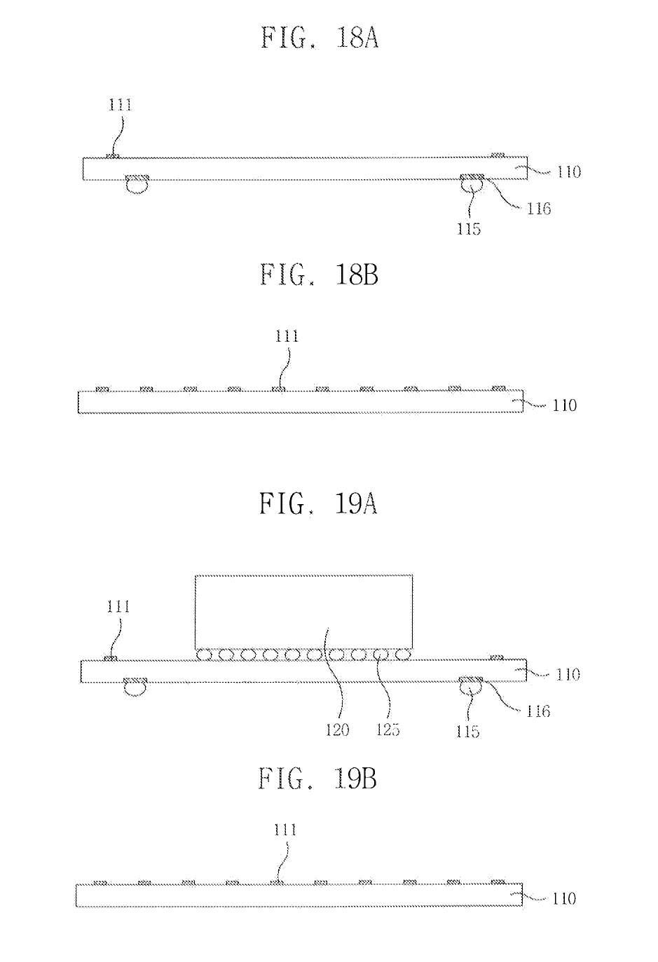

Thereafter, as shown in FIGS. 19A and 19B, the first method of fabricating the semiconductor package according to the embodiment of the general inventive concept may include mounting the semiconductor chip 120 on the interconnection substrate 110. The semiconductor chip 120 may be mounted on the interconnection substrate 110 using various techniques. For example, the semiconductor chip 120 may be mounted on the interconnection substrate 110 by a flip-chip technique using solder bumps 125.

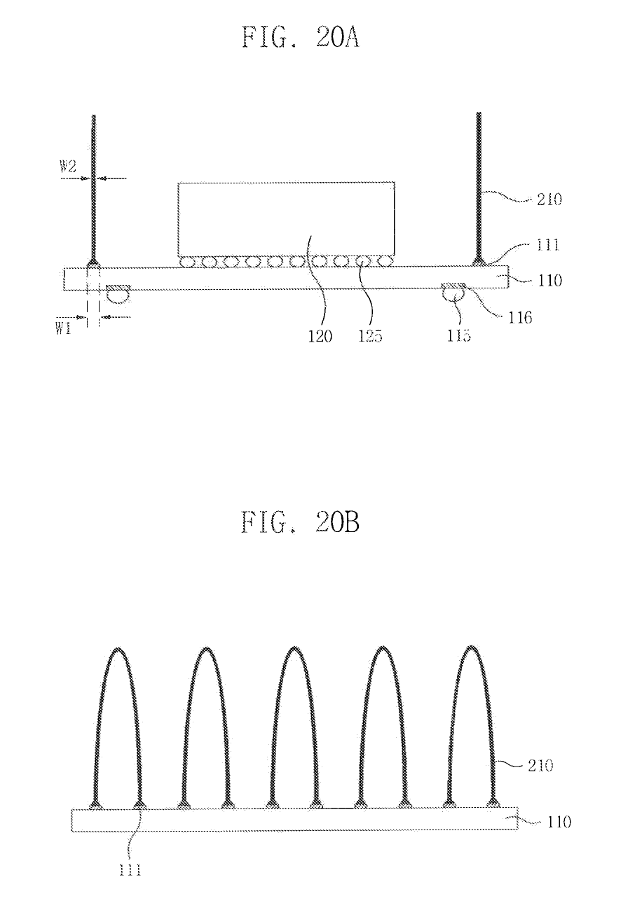

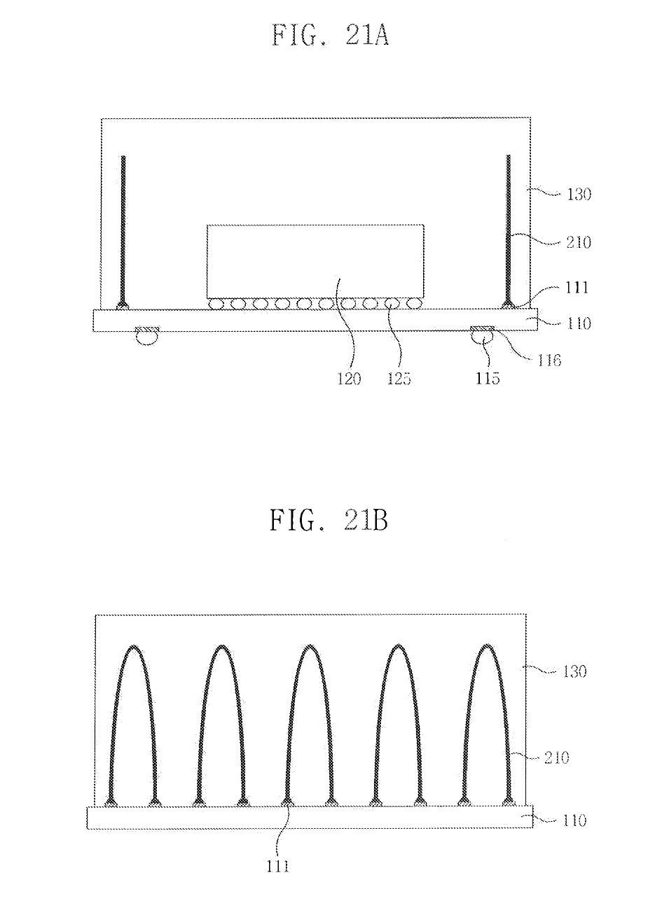

Next, as shown in FIGS. 20A and 20B, the first method of fabricating the semiconductor package according to the embodiment of the general inventive concept may include bonding a plurality of first lateral wires 210 to top surfaces of the plurality of ground pads 111. The plurality of first lateral wires 210 may have a second diameter W2 of about 20 to 100 and may be smaller than a first diameter W1 of the plurality of ground pads 111. The plurality of first lateral wires 210 may include at least one selected from the group including of Au, Cu, Al, and an alloy thereof.

The plurality of first lateral wires 210 may have loops with a predetermined height along the outline of the interconnection substrate 110. The plurality of first lateral wires 210 may directly connect two adjacent ones of the plurality of ground pads 111. Thus, the plurality of first lateral wires 210 may enclose a side surface of the semiconductor chip 120.

Subsequently, as shown in FIGS. 21A and 21B, the first method of fabricating the semiconductor package according to the embodiment of the general inventive concept may include forming a molding member 130 to cover the semiconductor chip 120 and the plurality of first lateral wires 210.

The molding member 130 may fill spaces between the plurality of first lateral wires 210 and the side surface of the semiconductor chip 120. Also, the molding member 130 may enclose side surfaces of the plurality of first lateral wires 210. The molding member 130 may be an EMC.

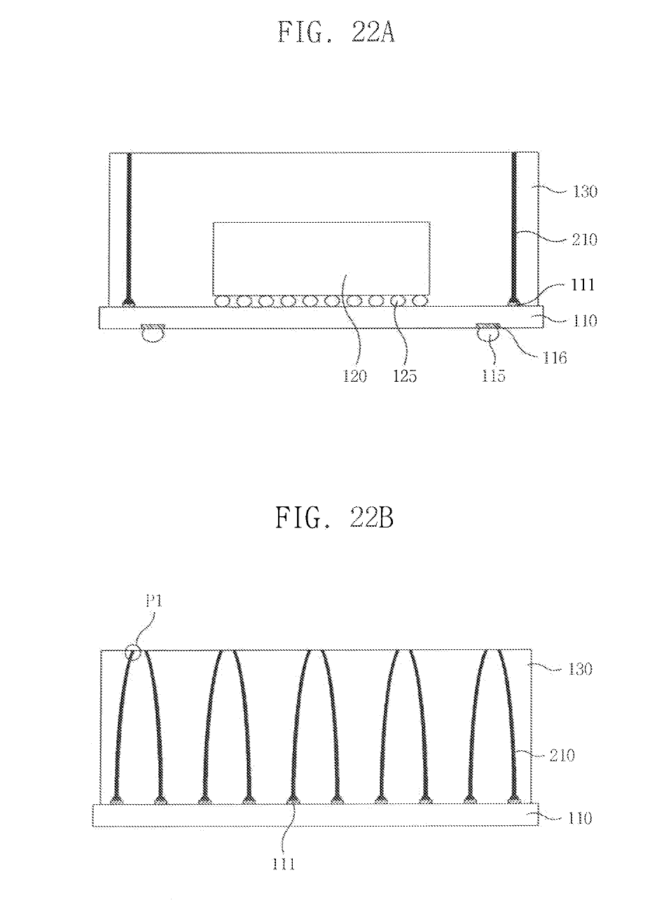

Thereafter, as shown in FIGS. 22A and 22B, the first method of fabricating the semiconductor package according to the embodiment of the general inventive concept may include planarizing the molding member 130 using a grinding process or a chemical mechanical polishing (CMP) process. The planarization of the molding member 130 may be performed until peaks P1 of the plurality of first lateral wires 210 are exposed in a top surface of the molding member 130.

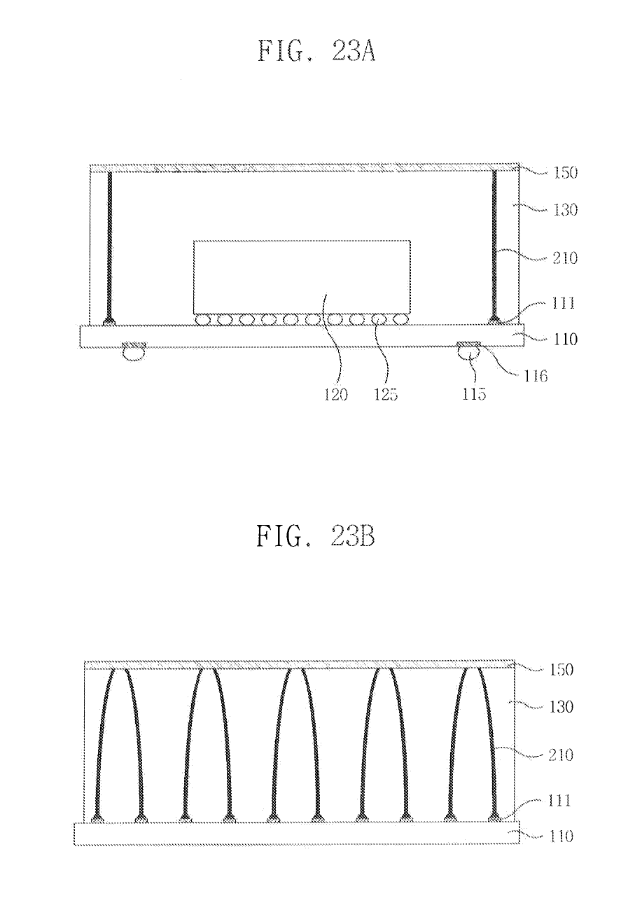

Afterwards, as shown in FIGS. 23A and 233, the first method of fabricating the semiconductor package according to the embodiment of the general inventive concept may include forming a metal layer 150 on the molding member 130. Thus, the metal layer 150 may be directly in contact with the peaks P1 of the plurality of first lateral wires 210.

The metal layer 150 may be formed using a CVD process, a PVD process, an ALD process, an electroless plating process, a screen printing process, or a Au or Ag pasting process.

### Method Embodiment 2

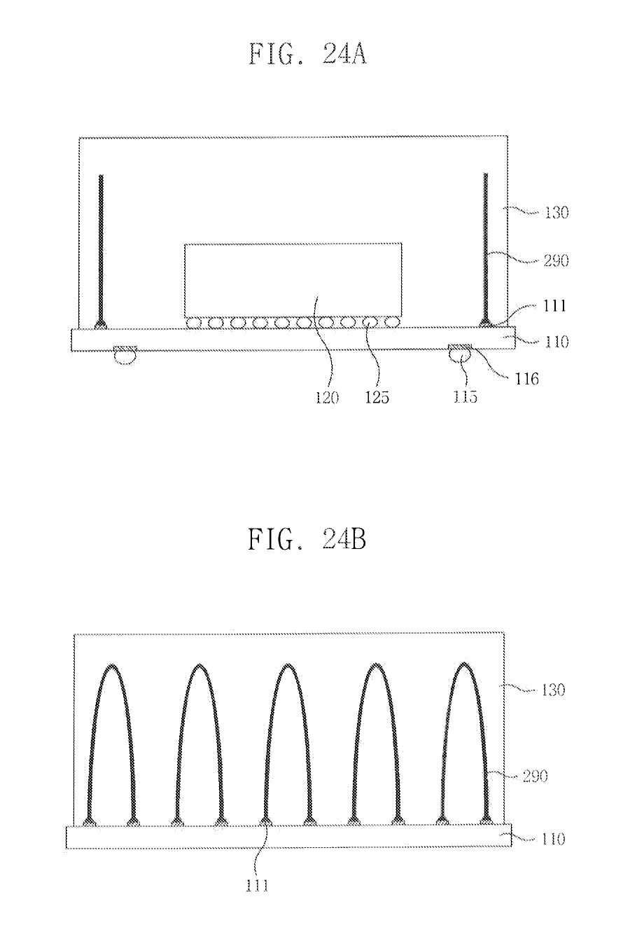

FIGS. 24A, 25A, and 26A are longitudinal sectional views taken along line X-X′ of FIG. 10, which illustrate a second method of fabricating a semiconductor package according to embodiments of the inventive concept, and FIGS. 24B, 25B and 26B are longitudinal sectional views taken along line XI-XI′ of FIG. 10, which illustrate the second method of fabricating the semiconductor package according to the embodiments of the inventive concept.

Hereinafter, only differences between the first and second methods of fabricating the semiconductor packages according to the embodiments of the inventive concept will be briefly described.

To begin with, as shown in FIGS. 24A and 24B, the second method of fabricating the semiconductor package according to the embodiment of the general inventive concept may include bonding a plurality of fifteenth lateral wires 290 to top surfaces of a plurality of ground pads 111 of an interconnection substrate 110. In this case, the plurality of fifteenth lateral wires 290 may enclose a side surface of a semiconductor chip 120 mounted on the interconnection substrate 110.

Thereafter, the second method of fabricating the semiconductor package according to the embodiment of the general inventive concept may include forming a molding member 130 to cover the semiconductor chip 120 and the plurality of fifteenth lateral wires 290.

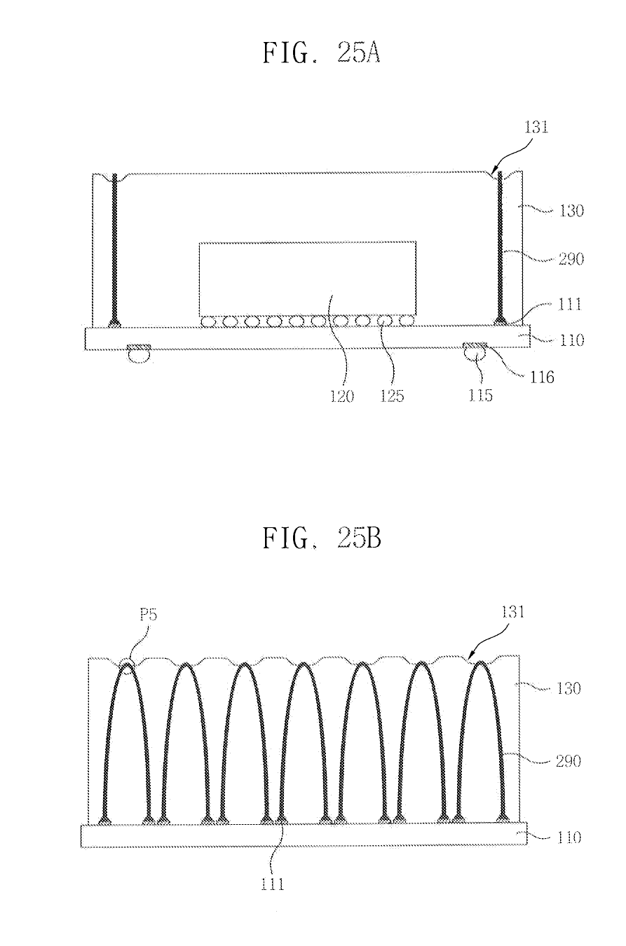

Subsequently, as shown in FIGS. 25A and 25B, the second method of fabricating the semiconductor package according to the embodiment may include forming a plurality of first grooves 131 in the molding member 130 to expose peaks P5 of the plurality of fifteenth lateral wires 290. The plurality of first grooves 131 may be formed using a laser drilling process (LDP).

According to the second method of fabricating the semiconductor package of the embodiment, it is illustrated that all the peaks P5 of the plurality of fifteenth lateral wires 290 are exposed by the plurality of first grooves 131. However, the second method of fabricating the semiconductor package according to the embodiment may include forming at least one second groove 132 to expose some peaks P6 of a plurality of sixteenth lateral wires 300 in the same manner as described in the eleventh embodiment.

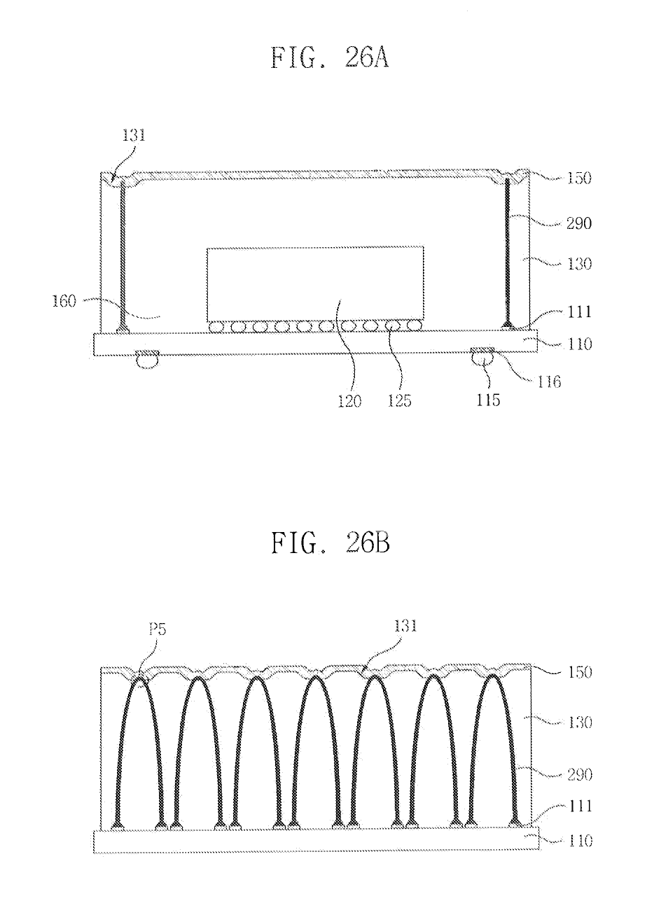

Afterwards, as shown in FIGS. 26A and 26B, the second method of fabricating the semiconductor package according to the embodiment may include forming a metal layer 150 on the molding member 130. Thus, the metal layer 150 may be directly in contact with the peaks P5 of the plurality of fifteenth lateral wires 290 exposed by the plurality of first grooves 131.

### Applied Embodiment

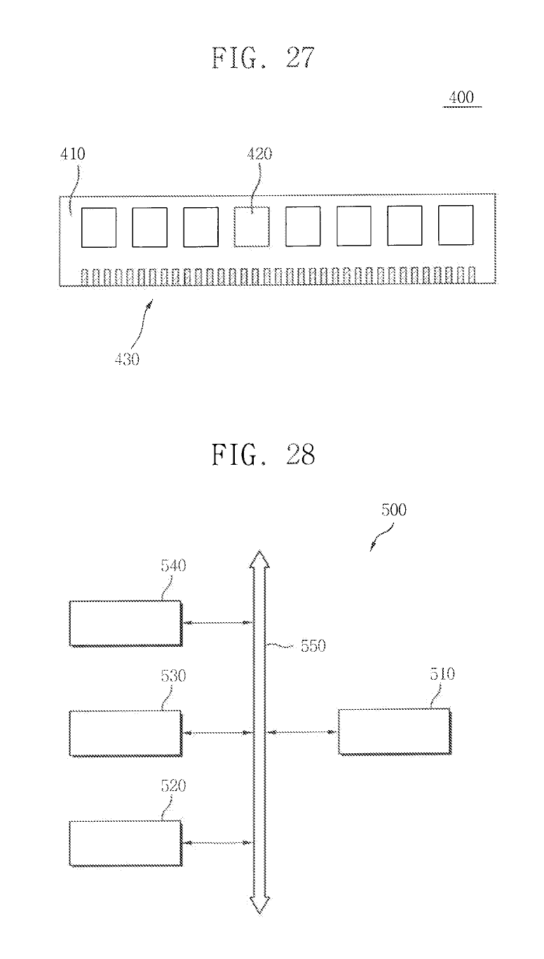

FIG. 27 is a construction diagram of a semiconductor module using a semiconductor package according to embodiments of the general inventive concept.

Referring to FIG. 27, a semiconductor module 400 using the semiconductor package according to the embodiments of the general inventive may include a module board 410, a plurality of semiconductor devices 420 mounted on the module board 410, and a plurality of contact terminals 430 disposed on one surface of the module board 410.

At least one of the plurality of semiconductor devices 420 may include a semiconductor package according to an embodiment of the general inventive concept. The module board 410 may be a PCB. The plurality of contact terminals 430 may be electrically connected to the plurality of semiconductor devices 420, respectively.

FIG. 28 is a construction diagram of an electronic system including a semiconductor package according to embodiments of the general inventive concept.

Referring to FIG. 28, an electronic system 500 including the semiconductor package according to the embodiments may include a controller 510, an input/output (I/O) device 520, a memory device 530, an interface 540, and a bus structure 550. The memory device 530 may include a semiconductor package according to an embodiment of the general inventive concept. The bus structure 550 may provide a path through which data is received and transmitted among the controller 510, the I/O device 520, the memory device 530, and the interface 540.

The controller 510 may include at least one selected from the group including at least one microprocessor (MP), a digital signal processor, a microcontroller, and logic devices capable of similar functions thereto. The I/O device 520 may include at least one selected from the group including a keypad, a keyboard, and a display device. The memory device 530 may function to store data and/or commands executed by the controller 510.

The memory device 530 may include a semiconductor package including one selected from the group including a volatile memory chip, a nonvolatile memory chip, and a combination thereof. The volatile memory chip may be a DRAM or an SRAM. The nonvolatile memory chip may be a flash memory device, a phase-change memory device, an MRAM, or a resistive random access memory (RRAM).

The interface 540 may transmit data to a communication network or receive data from the communication network. The interface 540 may be a wired/wireless interface. For example, the interface 540 may include an antenna or wired/wireless transceiver. The electronic system 500 may further include an application chipset, a camera image, a camera image processor (CIS), and an I/O device.

The electronic system 500 may be embodied by a mobile system, a personal computer (PC), an industrial computer, or a logic system capable of various functions. For example, the mobile system may be any one selected from the group including a personal digital assistant (PDA), a portable computer, a web tablet, a mobile phone, a wireless phone, a laptop computer, a memory card, a digital music system, and a data transmission/receiving system. When the electronic system 500 is a wireless communication apparatus, the electronic system 500 may be used for communication systems, such as a code division multiple access (CDMA) system, a global system for mobile communication (GSM), a North American digital cellular (NADC) system, an enhanced-time division multiple access (E-TDMA) system, a wideband code division multiple access (WCDAM) system, and a CDMA2000 system.

According to a semiconductor package and a method of fabricating the same of the general inventive concept, the semiconductor package may be combined with an electromagnetic shielding structure. Thus, electromagnetic interference (EMI) caused by a clock frequency of a semiconductor chip may be prevented without a change in the entire volume of the semiconductor package.

The foregoing is illustrative of embodiments and is not to be construed as limiting thereof. Although a few embodiments of the general inventive concept have been described in detail, those skilled in the art will readily appreciate that many modifications may be made in these embodiments without materially departing from the principles and spirit of the general inventive concept. Accordingly, all such modifications are intended to be included within the scope of the general inventive concept as defined in the claims. In the claims, means-plus-function clauses are intended to cover the structures described herein as performing the recited function, and not only structural equivalents but also equivalent structures. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A semiconductor package comprising:
an interconnection substrate;
a semiconductor chip mounted on the interconnection substrate;
a lateral wire bonded to the interconnection substrate and configured to enclose a side surface of the semiconductor chip; and
a metal layer disposed on the semiconductor chip and electrically connected to the lateral wire.

2. The package of claim 1, wherein the lateral wire has a loop with a predetermined height and is formed along an outer region of the interconnection substrate.

3. The package of claim 1, wherein the lateral wire is arranged in a plurality of columns.

4. The package of claim 3, wherein two adjacent columns of the lateral wire are bonded to cross each other.

5. The package of claim 1, further comprising a molding member disposed between a side surface of the semiconductor chip and the lateral wire and between a top surface of the semiconductor chip and the metal layer.

6. A semiconductor package comprising,
an interconnection substrate;
a semiconductor chip mounted on a central region of the interconnection substrate;
a plurality of ground pads formed on an outer region of the interconnection substrate;
a molding member configured to cover the semiconductor chip;
a metal layer formed on the molding member; and
a plurality of lateral wires configured to electrically connect at least one of the plurality of ground pads and the metal layer, and to enclose a side surface of the semiconductor chip,
wherein a peak of at least one of the plurality of lateral wires is exposed in a top surface of the molding member.

7. The package of claim 6, wherein the plurality of lateral wires electrically connect the plurality of ground pads to each other.

8. The package of claim 6, wherein a distance between two adjacent lateral wires of the plurality of lateral wires becomes different from the interconnection substrate to the metal layer.

9. The package of claim 8, wherein the two adjacent lateral wires of the plurality of lateral wires are bent toward each other.

10. The package of claim 8, wherein the two adjacent lateral wires of the plurality of lateral wires are bent away from each other.

11. The package of claim 6, wherein the plurality of ground pads are formed in a plurality of columns along the outer region of the interconnection substrate.

12. The package of claim 11, wherein the plurality of lateral wires electrically connect ground pads in one column of the plurality of ground pads to each other.

13. The package of claim 6, wherein two adjacent ground pads out of the plurality of ground pads are directly connected to one another by a corresponding one of the plurality of lateral wires.

14. The package of claim 6, wherein the molding member includes at least one groove by which the at least one peak of the plurality of lateral wires is exposed.

15. The package of claim 6, wherein at least one of the plurality of lateral wires connect at least one of the plurality of ground pads and the metal layer by the shortest route.

16. A semiconductor package comprising:
an interconnection substrate;
a semiconductor chip mounted on a central region of the interconnection substrate;
a plurality of lateral wires, each of the plurality of lateral wires having at least a first end bonded to an outer region of the interconnection substrate;
a molding member disposed on the interconnection substrate to cover the semiconductor chip and at least part of the plurality of lateral wires; and
a metal layer disposed on the molding member above the semiconductor chip and electrically connected to a second end of at least one of the plurality of lateral wires.

17. The semiconductor package of claim 16, wherein at least one of the plurality of lateral wires has an arch shape.

18. The semiconductor package of claim 16, wherein the molding member corresponding to the outer region is lower than the molding member corresponding to the central region.

19. The semiconductor package of claim 16, wherein the plurality of lateral wires surround lateral sides of the semiconductor chip.

20. The semiconductor package of claim 16, wherein the molding member includes grooves such that the plurality of lateral wires disposed in the area of the groove contact the metal layer and the plurality of lateral wires not disposed in the area of the groove do not contact the metal layer.
